(19) United States
(12) Patent Application Publication
(10) Pub. No.: US 2017/0014873 A1
(43) Pub. Date: Jan. 19, 2017

(54) SUBSTRATE PROCESSING SYSTEM AND PIPE CLEANING METHOD

(71) Applicant: SCREEN HOLDINGS CO., LTD., Kyoto (JP)

(72) Inventors: Ayumi HIGUCHI, Kyoto-shi (JP); Eri FUJITA, Kyoto-shi (JP); Hiroshi YOSHIDA, Kyoto-shi (JP); Masashi NOMURA, Kyoto-shi (JP)

(21) Appl. No.: 15/124,252

(22) PCT Filed: Feb. 26, 2015
(86) PCT No.: PCT/JP2015/001010

§ 371 Date: Sep. 7, 2016

(30) Foreign Application Priority Data
Mar. 10, 2014 (JP) 2014-046373
Mar. 27, 2014 (JP) 2014-065621

(51) Int. Cl. B08B 9/027; H01L 21/67

(52) U.S. Cl. CPC B08B 9/027; H01L 21/67051

(57) ABSTRACT

A substrate processing system is constituted by a cleaning unit, a plurality of processing liquid supply units and a substrate processing apparatus. The cleaning unit supplies a first cleaning liquid to a processing unit of a processing liquid supply unit during cleaning of a pipe. The processing liquid supply unit stores the first cleaning liquid supplied from the cleaning unit in the processing liquid tank, and then supplies the first cleaning liquid in a processing liquid tank to the processing unit of the substrate processing apparatus through the pipe. The cleaning unit prepares a second cleaning liquid concurrently with cleaning of the pipe by the first cleaning liquid, and supplies the prepared second cleaning liquid to the processing liquid tank.

### TECHNICAL FIELD

The present invention relates to a substrate processing system that performs processing on a substrate and a pipe cleaning method of cleaning a pipe.

### BACKGROUND ART

A substrate processing apparatus is used to perform various processing on a substrate such as a semiconductor wafer. For example, the substrate processing apparatus described in Patent Document 1 includes a plurality of processing units that process substrates with a processing liquid, and a processing liquid supplier that supplies the processing liquid to these processing units. The processing liquid supplier includes a plurality of processing liquid supply modules. During processing of the substrate, the processing liquid is supplied to a nozzle of each processing unit through a pipe from any one of the plurality of processing liquid modules. The processing liquid is discharged to the substrate from the nozzle.

In the case where such a substrate processing apparatus is installed in a factory or the like, before an operation of the substrate processing apparatus, contaminants such as particles that are present inside of the pipe, the nozzle and the like must be removed. Further, deposits that are produced in the pipe and the like during the use of the substrate processing apparatus must be removed at an appropriate time. Therefore, it is necessary to clean the pipe and the like of the substrate processing apparatus.

In the substrate processing apparatus described in Patent Document 1, three-way valves are provided in each processing liquid supply module. A processing liquid supply pipe and a cleaning liquid supply pipe are connected to each three-way valve. During processing of the substrate, the three-way valves are switched such that the processing liquid supplied from the processing liquid supply pipe is supplied to the processing unit. During the cleaning of the pipe and the like, the three-way valves are switched such that a cleaning liquid supplied from the cleaning liquid supply pipe is supplied to the processing unit. Thus, the pipe and the like are cleaned.

[Patent Document 1] JP 2010-147212 A

### SUMMARY OF INVENTION

### Technical Problem

In the substrate processing apparatus described in Patent Document 1, pure water is used as the cleaning liquid, for example. However, contaminants inside of the pipe and the like may not be removed by only pure water. In that case, it is necessary to perform cleaning with the cleaning liquid made of a chemical liquid. For example, in the case where the cleaning liquid made of a liquid mixture of a plurality of chemical liquids is used, it requires time to prepare the cleaning liquid. Further, it is necessary to clean away the liquid mixture with a rinse liquid as the cleaning liquid after the cleaning with the liquid mixture. In this manner, in the case where the pipe and the like are cleaned with the plurality of cleaning liquids, a time period required for a cleaning process is lengthened.

An object of the present invention is to provide a substrate processing system and a pipe cleaning method by which a cleaning time period required in the case where a pipe is cleaned with a plurality of cleaning liquids can be shortened.

### Solution to Problem

(1) A substrate processing system according to one aspect of the present invention includes a substrate processing apparatus that performs processing on a substrate, a processing liquid supply unit that supplies a processing liquid to the substrate processing apparatus through a pipe; and a cleaning unit, wherein the processing liquid supply unit includes a processing liquid tank that stores the processing liquid during processing of the substrate, the substrate processing apparatus includes a processing unit that supplies the processing liquid to the substrate during processing of the substrate, the processing liquid tank and the processing unit are connected to each other by the pipe, the cleaning unit is configured to, during cleaning of the pipe, supply a first cleaning liquid to the processing liquid tank of the processing liquid supply unit, then prepare a second cleaning liquid, and supply the prepared second cleaning liquid to the processing liquid tank, and the processing liquid supply unit is configured to, during the cleaning of the pipe, store the first cleaning liquid supplied from the cleaning unit in the processing liquid tank, and then clean the pipe by supplying the first cleaning liquid in the processing liquid tank to the processing unit through the pipe, and store the second cleaning liquid supplied from the cleaning unit in the processing liquid tank, and then clean the pipe by supplying the second cleaning liquid in the processing liquid tank to the processing unit through the pipe, and the cleaning unit prepares the second cleaning liquid concurrently with the cleaning of the pipe by the first cleaning liquid.

In the substrate processing system, during the processing of the substrate, the processing liquid is stored in the processing liquid tank of the processing liquid supply unit. The processing liquid stored in the processing liquid tank is supplied to the substrate processing apparatus through the pipe. In the substrate processing apparatus, the supplied processing liquid is supplied to the substrate by the processing unit, and the substrate is processed.

During the cleaning of the pipe, the first cleaning liquid is supplied from the cleaning unit to the processing liquid tank of the processing liquid supply unit. In the processing liquid supply unit, after the first cleaning liquid supplied from the cleaning unit is stored in the processing liquid tank, the first cleaning liquid in the processing liquid tank is supplied to the processing unit through the pipe. Thus, the pipe is cleaned by the first cleaning liquid.

In the cleaning unit, after the first cleaning liquid is supplied to the processing liquid tank, the second cleaning liquid is prepared concurrently with the cleaning of the pipe by the first cleaning liquid. The prepared second cleaning liquid is supplied to the processing liquid tank of the processing liquid supply unit. In the processing liquid supply unit, after the second cleaning liquid supplied from the cleaning unit is stored in the processing liquid tank, the second cleaning liquid in the processing liquid tank is supplied to the processing unit through the pipe. Thus, the pipe is cleaned by the second cleaning liquid.

In this manner, because the second cleaning liquid is prepared concurrently with the cleaning of the pipe by the first cleaning liquid, a time period required for the cleaning of the pipe by the first cleaning liquid and the second cleaning liquid can be shortened. As a result, a cleaning time period required in the case where the pipe is cleaned with a plurality of cleaning liquids can be shortened.

(2) The substrate processing system may further include a supply path for supplying the first cleaning liquid and the second cleaning liquid from the cleaning unit to the processing liquid tank, and an opening closing device that opens and closes the supply path, wherein the opening closing device may open the supply path during supply of the first cleaning liquid from the cleaning unit to the processing liquid tank and close the supply path after the supply of the first cleaning liquid to the processing liquid tank.

In this case, after the supply of the first cleaning liquid, the cleaning unit and the processing liquid tank are separated from each other. Therefore, preparation of the second cleaning liquid can be started in the cleaning unit right after the end of the supply of the first cleaning liquid from the cleaning unit to the processing liquid tank. Thus, a cleaning time period required in the case where the pipe is cleaned with a plurality of cleaning liquids can be shortened.

(3) The substrate processing system may further include an inert gas supplier that supplies an inert gas to the supply path and the cleaning unit after the cleaning of the pipe by the second cleaning liquid.

In this case, because an inert gas is sealed in the supply path and the processing unit after the cleaning of the pipe, contamination in the supply path and the cleaning unit due to entry of particles and the like is prevented.

(4) The cleaning unit may be provided to be connectable to and disconnectable from the processing liquid supply unit.

In this case, the cleaning unit can be connected to the processing liquid supply unit during the cleaning of the pipe, and the cleaning unit can be disconnected from the processing liquid supply unit after the cleaning of the pipe. Therefore, it is possible to sequentially clean the pipes in the plurality of processing liquid supply units and the plurality of substrate processing apparatuses by sequentially connecting the cleaning unit to the plurality of processing liquid supply units. Further, because the cleaning unit can be disconnected during processing of the substrate, the size of the substrate processing system is inhibited from increasing.

(5) The processing liquid supply unit may include a plurality of the processing liquid tanks, and the cleaning unit may be configured to be connectable to the plurality of processing liquid tanks.

In this case, a plurality of pipes that connect the plurality of processing liquid tanks to the substrate processing apparatus can be cleaned by a single cleaning unit.

(6) The processing liquid supply unit may further include a circulation path that circulates the first cleaning liquid in the processing liquid tank through a filter, and the cleaning unit may prepare the second cleaning liquid concurrently with circulation of the first cleaning liquid by the circulation path.

In this case, particles mixed in the first cleaning liquid are removed by the filter. Further, the second cleaning liquid is prepared concurrently with the circulation of the first cleaning liquid by the circulation path and the cleaning of the pipe by the first cleaning liquid. Therefore, even in the case where a relatively long time period is required for the preparation of the second cleaning liquid, a time period required for the cleaning of the pipe by the first cleaning liquid and the second cleaning liquid is inhibited from increasing.

(7) The substrate processing system may further include a gas supply system configured to supply gas to the pipe in at least one period of a first period in which the first cleaning liquid is supplied to the pipe and a second period in which the second cleaning liquid is supplied to the pipe.

In this case, the pipe can be sufficiently cleaned by the effect of the gas continuously supplied to the first cleaning liquid or the second cleaning liquid.

(8) The gas supply system may be configured to continuously supply an amount of the gas that is a supply amount of the first cleaning liquid per unit time or more to the first cleaning liquid supplied to the pipe in the first period.

In this case, the pipe can be sufficiently cleaned by the effect of the gas continuously supplied to the first cleaning liquid.

(9) The gas supply system may be configured to continuously supply an amount of the gas that is a supply amount of the second cleaning liquid per unit time or more to the second cleaning liquid supplied to the pipe in the second period.

In this case, the pipe can be sufficiently cleaned by the effect of the gas continuously supplied to the second cleaning liquid.

(10) The pipe may constitute a circulation path that returns the processing liquid sent from the processing liquid tank to the processing liquid tank, and a discharge path that supplies the processing liquid from the circulation path to the processing unit, and the gas supply system may be configured to supply the gas to the circulation path in the at least one period.

In this case, a flow speed of the first cleaning liquid or the second cleaning liquid circulating through the circulation path can be increased by the effect of the gas. The discharge path can be effectively cleaned by the supply of this cleaning liquid to the discharge path.

(11) The substrate processing apparatus may include a processing chamber, and a nozzle that discharges the processing liquid supplied from the circulation path through the discharge path to the substrate in the processing chamber, wherein a valve may be provided at the discharge path, and a cleaning liquid that circulates through the circulation path may be discharged from the nozzle intermittently by intermittent opening of the valve.

In this case, it is possible to sufficiently clean the nozzle and the discharge path without decreasing the pressure and speed of the first cleaning liquid or the second cleaning liquid circulating through the circulation path.

(12) The substrate processing apparatus may include a plurality of the processing chambers, and a plurality of the nozzles respectively provided in the plurality of the processing chambers, the pipe may constitute a plurality of the discharge paths, a plurality of the valves may be provided at the plurality of discharge paths, respectively, and the plurality of valves may be opened at time points different from one another in the at least one period.

In this case, because the first cleaning liquid or the second cleaning liquid is not simultaneously discharged from the plurality of discharge paths, decreases in pressure and speed of the first cleaning liquid or the second cleaning liquid circulating through the circulation path can be prevented. Thus, each nozzle and each discharge path can be sufficiently cleaned.

(13) The gas supply system may continuously supply an amount of the gas that is larger than an amount of the first cleaning liquid or the second cleaning liquid supplied per unit time in the at least one period such that gas is discharged from the plurality of nozzles.

In this case, the pipe that constitutes the plurality of discharge paths can be effectively cleaned by the effect of a large amount of the supplied gas.

(14) The gas supply system may further include a pipe path that supplies the gas in a direction same as a direction of a flow of the first cleaning liquid or the second cleaning liquid to the first cleaning liquid or the second cleaning liquid that circulates through the circulation path in the at least one period, and the pipe path may have an inner diameter smaller than an inner diameter of the circulation path.

In this case, the gas can be supplied to the first cleaning liquid or the second cleaning liquid circulating through the circulation path with no occurrence of a reverse flow and a pressure loss. As a result, the circulation speed of the first cleaning liquid or the second cleaning liquid circulating through the circulation path can be increased.

(15) A pipe cleaning method according to another aspect of the present invention of cleaning a pipe in a substrate processing apparatus and a processing liquid supply unit, wherein the processing liquid supply unit is configured to, during processing of a substrate, supply a processing liquid from a processing liquid tank of the processing liquid supply unit to a processing unit of the substrate processing apparatus through the pipe, the pipe cleaning method includes the steps of supplying a first cleaning liquid to the processing liquid tank of the processing liquid supply unit from a cleaning unit during cleaning of the pipe, cleaning the pipe by supplying the first cleaning liquid from the processing liquid tank to the processing unit of the substrate processing apparatus through the pipe after the supply of the first cleaning liquid to the processing liquid tank, preparing a second cleaning liquid in the cleaning unit concurrently with the cleaning of the pipe by the first cleaning liquid, supplying the second cleaning liquid from the cleaning unit to the processing liquid tank after the cleaning of the pipe by the first cleaning liquid, and cleaning the pipe by supplying the second cleaning liquid from the processing liquid tank to the processing unit through the pipe after the supply of the second cleaning liquid to the processing liquid tank.

In the pipe cleaning method, because the second cleaning liquid is prepared concurrently with the cleaning of the pipe by the first cleaning liquid, a cleaning time period required in the case where a time period required for cleaning of the pipe by the first cleaning liquid and the second cleaning liquid is shortened can be shortened. As a result, a cleaning time period required in the case where the pipe is cleaned with a plurality of cleaning liquids can be shortened.

### Advantageous Effects of Invention

The present invention enables a cleaning time period required in the case where the pipe is cleaned with the plurality of cleaning liquids to be shortened.

### BRIEF DESCRIPTION OF DRAWINGS

FIG. 1 is a schematic diagram showing the configuration of a substrate processing system according to a first embodiment of the present invention.

FIG. 2 is a flow chart showing a pipe cleaning operation by control of a controller of FIG. 1.

FIG. 3 is a schematic diagram showing the pipe cleaning operation of the substrate processing system in each step of FIG. 2.

FIG. 4 is a schematic diagram showing the pipe cleaning operation of the substrate processing system in each step of FIG. 2.

FIG. 5 is a schematic diagram showing the pipe cleaning operation of the substrate processing system in each step of FIG. 2.

FIG. 6 is a schematic diagram showing the pipe cleaning operation of the substrate processing system in each step of FIG. 2.

FIG. 7 is a schematic diagram showing the pipe cleaning operation of the substrate processing system in each step of FIG. 2.

FIG. 8 is a schematic diagram showing the pipe cleaning operation of the substrate processing system in each step of FIG. 2.

FIG. 9 is a schematic diagram showing the pipe cleaning operation of the substrate processing system in each step of FIG. 2.

FIG. 10 is a schematic diagram showing the pipe cleaning operation of the substrate processing system in each step of FIG. 2.

FIG. 11 is a schematic diagram showing the pipe cleaning operation of the substrate processing system in each step of FIG. 2.

FIG. 12 is a schematic diagram showing the configuration of a substrate processing system according to a second embodiment of the present invention.

FIG. 13 is a schematic diagram showing the configuration of a cleaning unit in a third embodiment of the present invention.

FIG. 14 is a schematic diagram showing the configuration of a substrate processing system including another example of a cleaning unit.

FIG. 15 is an explanatory view showing a nitrogen gas being mixed in a circulating cleaning liquid at a connector.

FIG. 16 is a schematic diagram showing a cleaning liquid flowing through a pipe in the case where a nitrogen gas is not supplied.

FIG. 17 is a schematic diagram showing the cleaning liquid flowing through the pipe in the case where a nitrogen gas is supplied.

FIG. 18 is a flow chart showing a cleaning procedure of the pipe of the substrate processing system with a cleaning unit and a substrate processing apparatus of FIG. 14.

FIG. 19 is a schematic diagram showing the configuration of a main part of a processing liquid supply unit in a fourth embodiment.

FIG. 20 is a schematic diagram showing the configuration of a main part of a processing liquid supply unit in a fifth embodiment.

### DESCRIPTION OF EMBODIMENTS

A substrate processing system and a pipe cleaning method according to one embodiment of the present invention will be describe below. In the following description, a substrate refers to a semiconductor wafer, a glass substrate for a photomask, a glass substrate for a liquid crystal display device, a glass substrate for a plasma display, a substrate for an optical disc, a substrate for a magnetic disc, a substrate for a magneto-optical disc or the like.

### [1] First Embodiment

### (1) Overall Configuration of Substrate Processing System

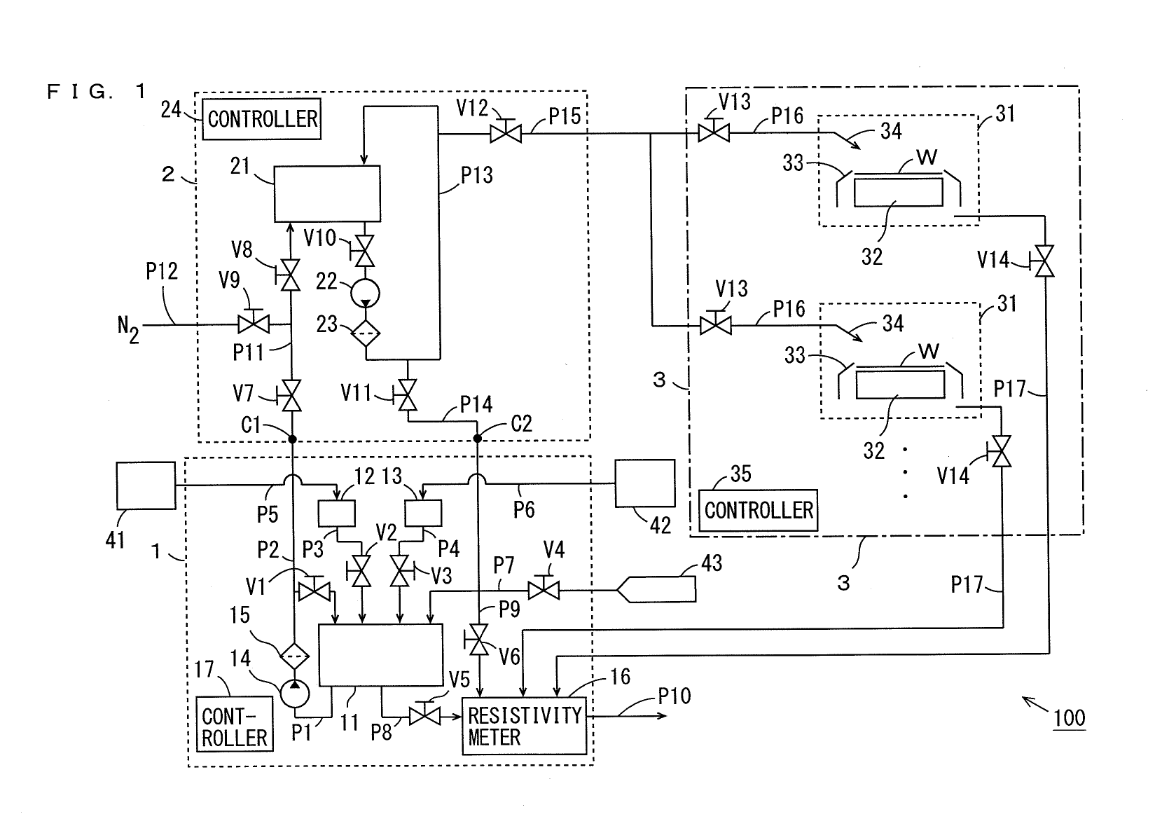

FIG. 1 is a schematic diagram showing the configuration of the substrate processing system according to the first embodiment of the present invention.

The substrate processing system 100 of FIG. 1 is constituted by a portable cleaning unit 1, a plurality of processing liquid supply units 2 and a substrate processing apparatus 3. The substrate processing apparatus 3 includes a plurality of processing units (processing chambers) 31. In FIG. 1, two processing units 31 are shown. In each processing unit 31, processing with a processing liquid is performed on a substrate W.

The cleaning unit 1 includes a cleaning liquid tank 11, weighing tanks 12, 13, a pump 14, a filter 15, a resistivity meter 16 and a controller 17. A pipe P1 for liquid circulation is connected between a liquid inlet port and a liquid outlet port of the cleaning liquid tank 11. A valve V1, the pump 14 and the filter 15 are inserted into the pipe P1. A pipe P2 is provided to branch from the pipe P1. The pipe P2 is connected to a connector C1 of the processing liquid supply unit 2.

The weighing tanks 12, 13 are connected to liquid inlet ports of the cleaning liquid tank 11 through pipes P3, P4, respectively. Valves V2, V3 are inserted into the pipes P3, P4, respectively. Chemical liquid supply units 41, 42 are connected to the weighing tanks 12, 13 through pipes P5, P6, respectively. Further, a pure water supply source 43 is connected to a liquid inlet port of the cleaning liquid tank 11 through a pipe P7. A valve V4 is inserted into the pipe P7.

A first chemical liquid is supplied from the chemical liquid supply unit 41 to the weighing tank 12, and a second chemical liquid is supplied from the chemical liquid supply unit 42 to the weighing tank 13. In this case, when the valves V2, V3 are opened, the first and second chemical liquids in the weighing tanks 12, 13 are supplied to the cleaning liquid tank 11, and the first and second chemical liquids are mixed. Thus, a cleaning liquid is produced. The first chemical liquid is ammonia, for example, and the second chemical liquid is hydrogen peroxide water, for example. In this case, a liquid mixture of ammonia and hydrogen peroxide water (hereinafter referred to as SC1) is produced as the cleaning liquid. In the case where the first chemical liquid is hydrochloric acid (HCl) and the second chemical liquid is hydrogen peroxide water, a liquid mixture of hydrochloric acid and hydrogen peroxide water (hereinafter referred to as SC2) is produced as the cleaning liquid.

When the valve V4 is opened, pure water is supplied from the pure water supply source 43 to the cleaning liquid tank 11. In this case, pure water is used as the cleaning liquid. Instead of pure water, a rinse liquid other than pure water may be used as the cleaning liquid. In this case, as the rinse liquid, carbonated water, ozone water, magnetic water, regenerated water (hydrogen water), or ionic water, or an organic solvent such as IPA (isopropyl alcohol) may be used, for example.

The liquid outlet port of the cleaning liquid tank 11 is connected to the resistivity meter 16 through a pipe P8. A valve V5 is inserted into the pipe P8. A pipe P9 is connected to the resistivity meter 16. A valve V6 is inserted into the pipe P9. The pipe P9 is connected to a connecter C2 of the processing liquid supply unit 2. Further, a pipe P10 for drainage is connected to the resistivity meter 16. The controller 17 controls operations of the cleaning unit 1 such as opening and closing of the valves V1 to V6 and an operation of the pump 14.

The processing liquid supply unit 2 includes one or a plurality of processing liquid tanks 21 and a controller 24. In the present embodiment, one processing liquid tank 21 is provided. A pipe P11 is connected between a liquid inlet port of the processing liquid tank 21 and the connector C1. Valves V7, V8 are inserted into the pipe P11. A pipe P12 is connected to a portion of the pipe P11 between the valves V7, V8. A valve V9 is inserted into the pipe P12. A nitrogen gas can be supplied to the pipe P11 through the P12.

A pipe P13 for liquid circulation is connected between a liquid inlet port and a liquid outlet port of the processing liquid tank 21. A valve V10, a pump 22 and a filter 23 are inserted into the pipe P13. A pipe P14 is provided to branch from the pipe P13. A valve V11 is inserted into the pipe P14. The pipe P14 is connected to the connector C2.

Further, a pipe P15 is provided to branch from the pipe P13. A valve V12 is inserted into the pipe P15. A plurality of pipes P16 branch from the pipe P15.

During processing of the substrate in the substrate processing apparatus 3, the processing liquid is stored in the processing liquid tank 21 of the processing liquid supply unit 2. As the processing liquid, a chemical liquid or a rinse liquid is used. As the chemical liquid, an aqueous solution such as buffered hydrogen fluoride (BHF), diluted hydrofluoric acid (DHF), hydrofluoric acid (hydrogen fluoride water:HF), hydrochloric acid, sulfuric acid, nitric acid, phosphoric acid, acetic acid, oxalic acid or ammonia water, or a liquid mixture of these may be used, for example. The processing liquid may be a photo resist liquid, a development liquid or the like.

The controller 24 controls operations of the processing liquid supply unit 2 such as opening and closing of the valves V7 to V12 and an operation of the pump 22. The substrate processing apparatus 3 includes the plurality of processing units 31. Each processing unit 31 includes a substrate holder 32 holding the substrate W, a cup 33 and a nozzle 34. The nozzle 34 is connected to the pipe P16. A valve V13 is inserted into each pipe P16. A pipe P17 is connected to a discharge port of each processing unit 31. A valve V14 is inserted into a pipe P17. The pipe P17 is connected to the resistivity meter 16 of the cleaning unit 1. A controller 35 controls operations of the substrate processing apparatus 3 such as opening and closing of the valves V13, V14.

The cleaning unit 1 is connectable to and disconnectable from the processing liquid supply unit 2 at connectors C1, C2. During a pipe cleaning operation, described below, the cleaning unit 1 is connected to the processing liquid supply unit 2. Further, during the processing of the substrate W, the cleaning unit 1 is disconnected from the processing liquid supply unit 2.

(2) Pipe Cleaning Operation

Next, the pipe cleaning operation in the substrate processing system 100 will be described. The controller 17 of the cleaning unit 1, the controller 24 of the processing liquid supply unit 2 and the controller 35 of the substrate processing apparatus 3 respectively control operations of the cleaning unit 1, the processing liquid supply unit 2 and the substrate processing apparatus 3 while communicating with one another.

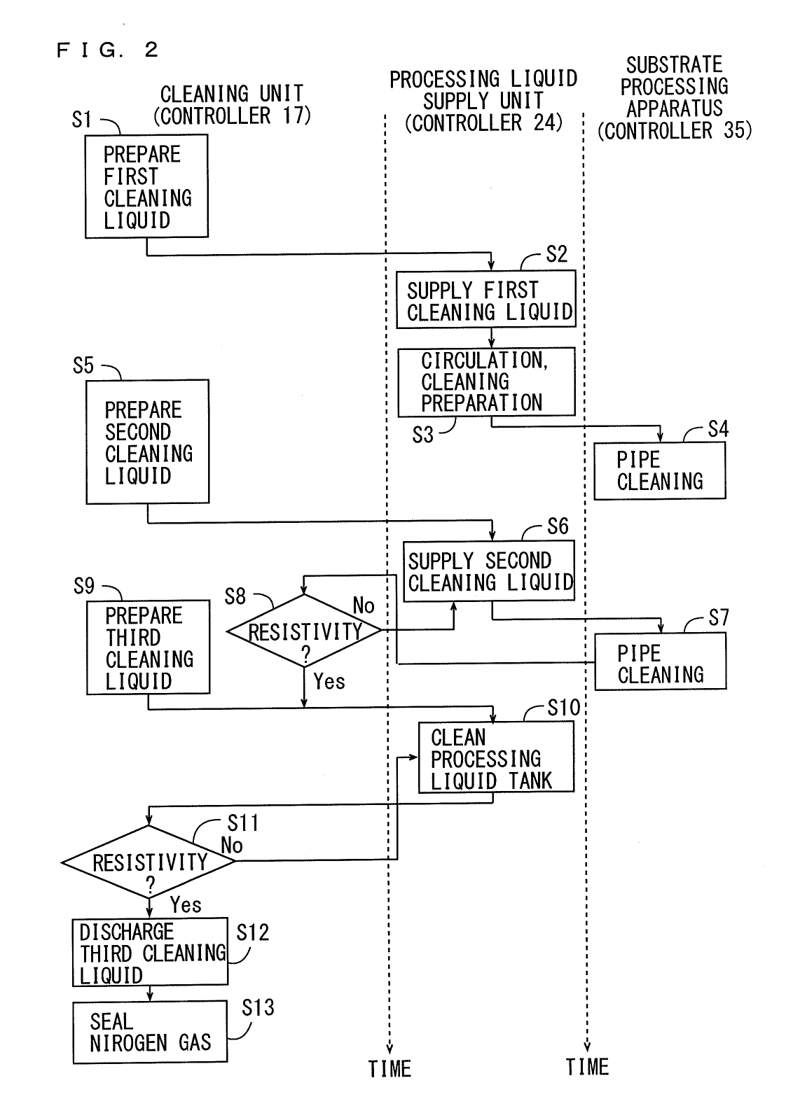

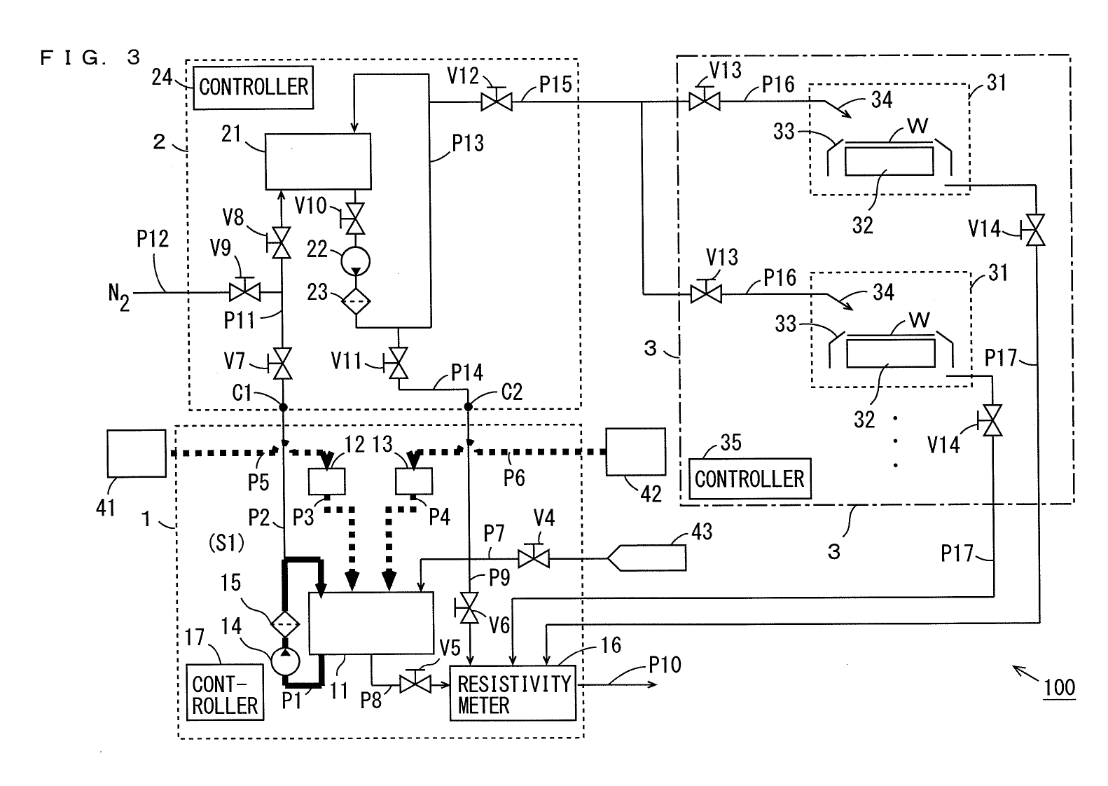

FIG. 2 is a flow chart showing the pipe cleaning operation by control of the controllers 17, 24, 35 of FIG. 1. FIGS. 3 to 11 are schematic diagrams showing the pipe cleaning operation of the substrate processing system 100 in each step of FIG. 2.

Here, an example in which the pipes of the processing liquid supply unit 2 and the substrate processing apparatus 3 are cleaned with a first cleaning liquid, a second cleaning liquid and a third cleaning liquid will be described. In the present example, the first cleaning liquid is the SC1, the second cleaning liquid is pure water and the third cleaning liquid is also pure water. In an initial state, the valves V1 to V14 are to be closed.

First, the cleaning unit 1 prepares the first cleaning liquid by control of the controller 17 (step S1 of FIG. 2). In this case, the controller 17 opens the valves V2, V3 of FIG. 1. Thus, as indicated by thick dotted arrows in FIG. 3, ammonia is supplied from the weighing tank 12 to the cleaning liquid tank 11 as the first chemical liquid, and hydrogen peroxide water is supplied from the weighing tank 13 to the cleaning liquid tank 11 as the second chemical liquid. Thus, ammonia and hydrogen peroxide water are mixed. As a result, the SC1 is produced as the first cleaning liquid. Thereafter, the controller 17 closes the valves V2, V3 and opens the valve V1 of FIG. 1, and operates the pump 14. Thus, as indicated by a thick solid arrow in FIG. 3, the first cleaning liquid circulates through the pipe P1. As a result, particles in the cleaning liquid tank 11 and particles included in the first cleaning liquid are removed by the filter 15.

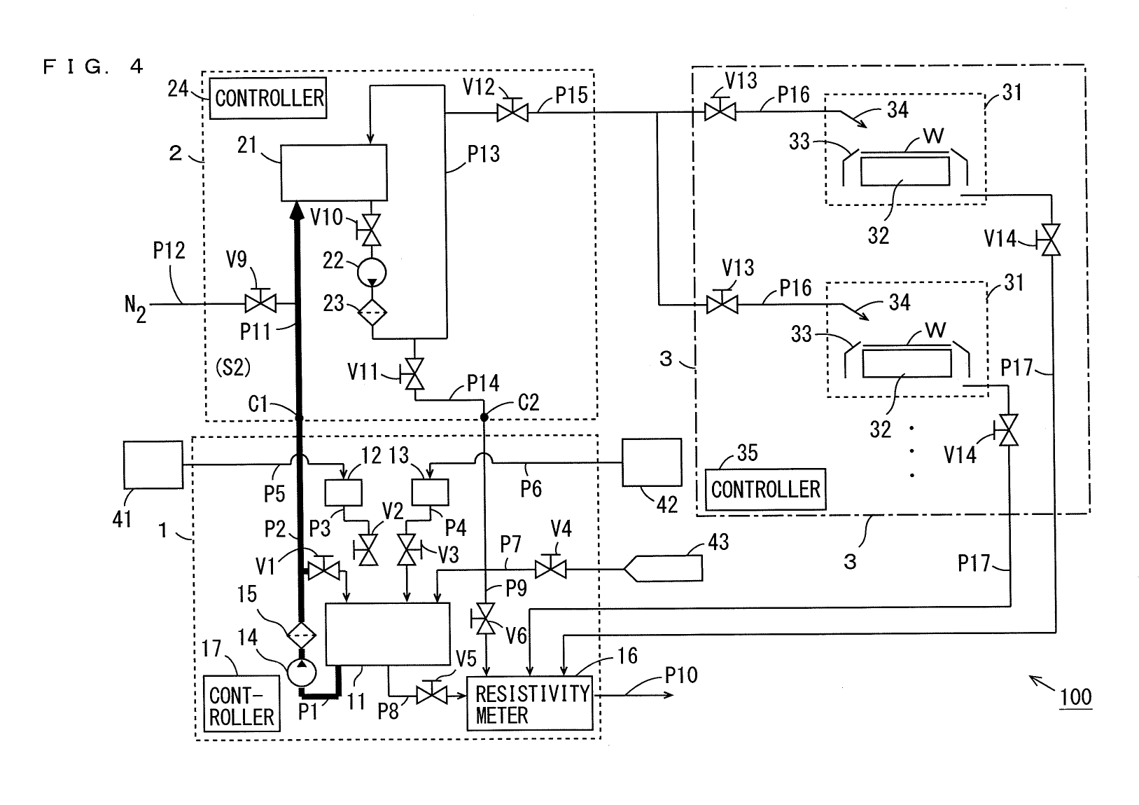

Next, the first cleaning liquid is supplied from the cleaning liquid tank 11 to the processing liquid tank 21 by control of the controller 24 (step S2). In this case, after the controller 17 closes the valve V1 of FIG. 1 to stop the return of the first cleaning liquid to the cleaning liquid tank 11, the controller 24 opens the valves V7, V8 of FIG. 1. Thus, as indicated by a thick solid arrow in FIG. 4, the first cleaning liquid is supplied from the pipe P1 to the processing liquid tank 21 through the pipe P11.

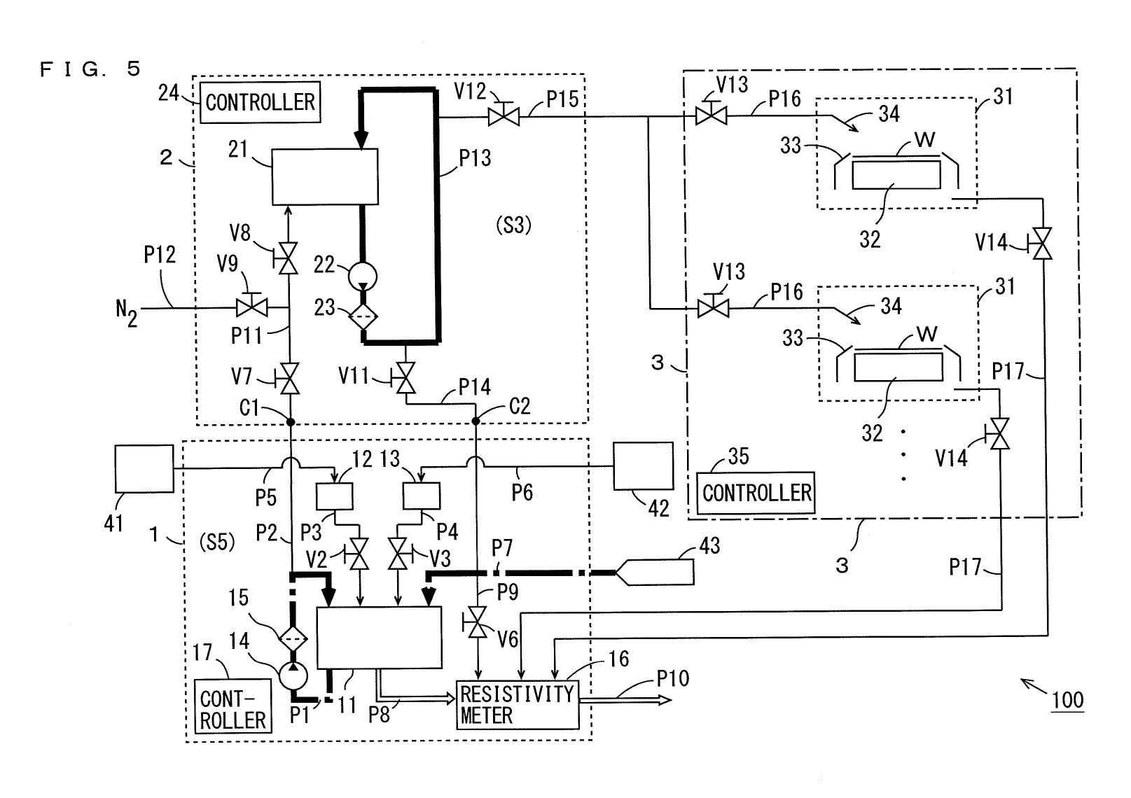

Thereafter, circulation of the first cleaning liquid and cleaning preparation are performed by control of the controller 24 (step S3). In this case, the controller 24 closes the valves V7, V8 of FIG. 1 and opens the valve V10, and operates the pump 22. Thus, as indicated by a thick solid arrow in FIG. 5, the first cleaning liquid circulates through the pipe P13, and particles in the processing liquid tank 21 and particles included in the first cleaning liquid are removed by the filter 23.

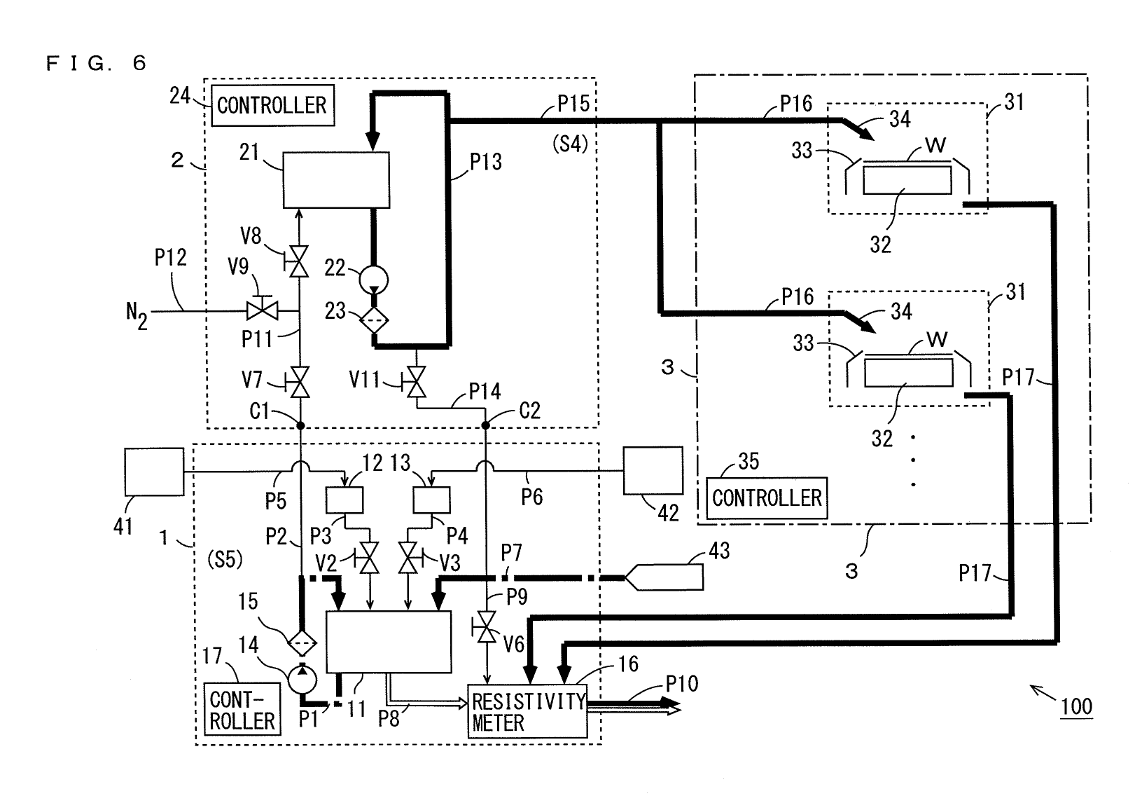

Then, the pipe cleaning is performed by control of the controller 24 and the controller 35 (step S4). In this case, the controller 24 opens the valve V12 of FIG. 1, and the controller 35 opens the valves V13, V14 of FIG. 1. Thus, as indicated by thick solid arrows in FIG. 6, the first cleaning liquid is supplied from the pipe P13 to each processing unit 31 through the pipes P15, P16 and the nozzles 34. The first cleaning liquid in each processing unit 31 is discharged through the pipes P17, P10. Thus, the pipe P13, P15 to P17, the valves V12 to V14 and the nozzles 34 are cleaned by the first cleaning liquid. After the end of the pipe cleaning by the first cleaning liquid, the controller 24 closes the valves V10, V12, and the controller 35 closes the valves V13, V14.

Concurrently with circulation of the first cleaning liquid and cleaning preparation of the step S3 and pipe cleaning of the step S4, the second cleaning liquid is prepared by control of the controller 17 (step S5). In this case, the controller 17 opens the valves V1, V4, V5 of FIG. 1. Thus, as indicated by thick one-dot and dash arrows in each of FIGS. 5 and 6, pure water is supplied from the pure water supply source 43 to the cleaning liquid tank 11 through the pipe P7 as the second cleaning liquid. As indicated by outlined arrows in each of FIGS. 5 and 6, the first cleaning liquid in the cleaning liquid tank 11 is discharged through the pipes P8, P10. Further, the second cleaning liquid circulates through the pipe P1. As a result, the first cleaning liquid in the cleaning liquid tank 11, the pipe P1, the pump 14 and the filter 15 is replaced with the second cleaning liquid. Further, the controller 17 measures resistivity (specific resistance) of the second cleaning liquid by the resistivity meter 16. When the resistivity becomes a predetermined value, the controller 17 closes the valve V5 of FIG. 1, and stores the second cleaning liquid in the cleaning liquid tank 11. Thereafter, the controller 17 closes the valve V4 of FIG. 1.

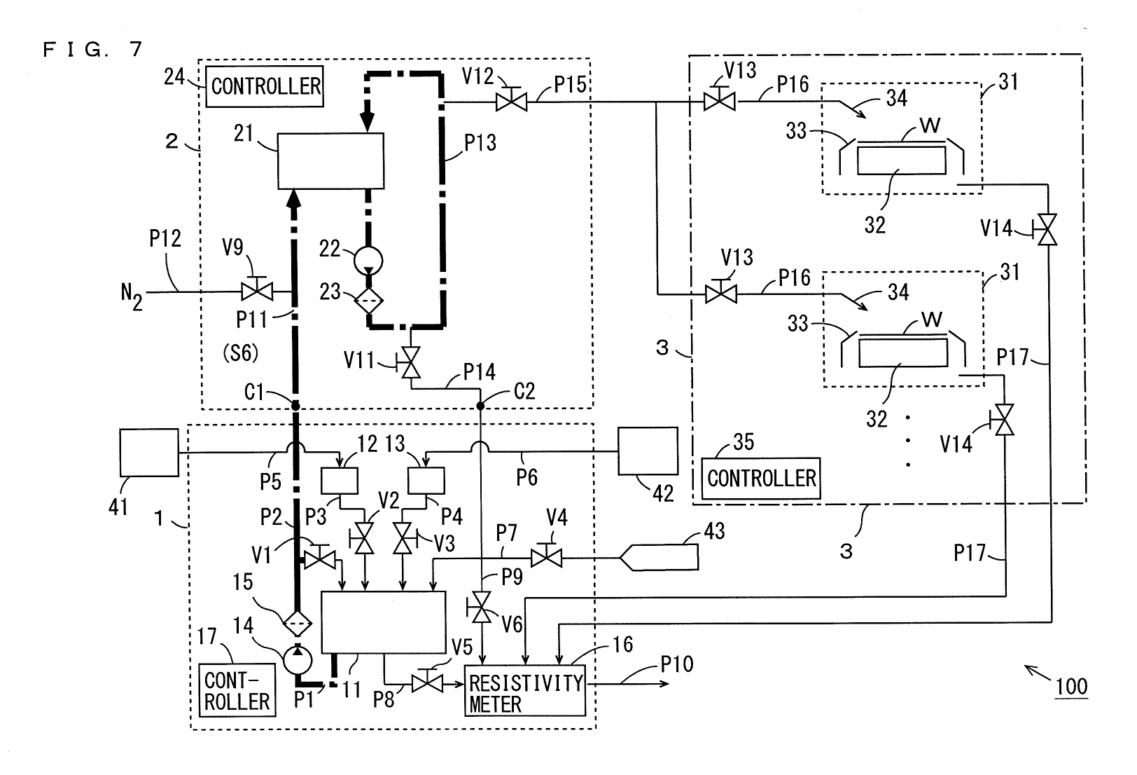

Next, the second cleaning liquid is supplied from the cleaning liquid tank 11 to the processing liquid tank 21 by control of the controller 24 (step S6). In this case, after the controller 17 closes the valve V1 of FIG. 1 to stop the return of the second cleaning liquid to the cleaning liquid tank 11, the controller 24 opens the valves V7, V8 of FIG. 1. Thus, as indicated by one thick one-dot and dash arrows in FIG. 7, the second cleaning liquid is supplied from the pipe P1 to the processing liquid tank 21 through the pipe P11. Further, the controller 24 opens the valve V10. Thus, the second cleaning liquid circulates through the pipe P13, and the first cleaning liquid in the cleaning liquid tank 11, the pipe P13, the filter 15 and the pump 14 is cleaned away by the second cleaning liquid.

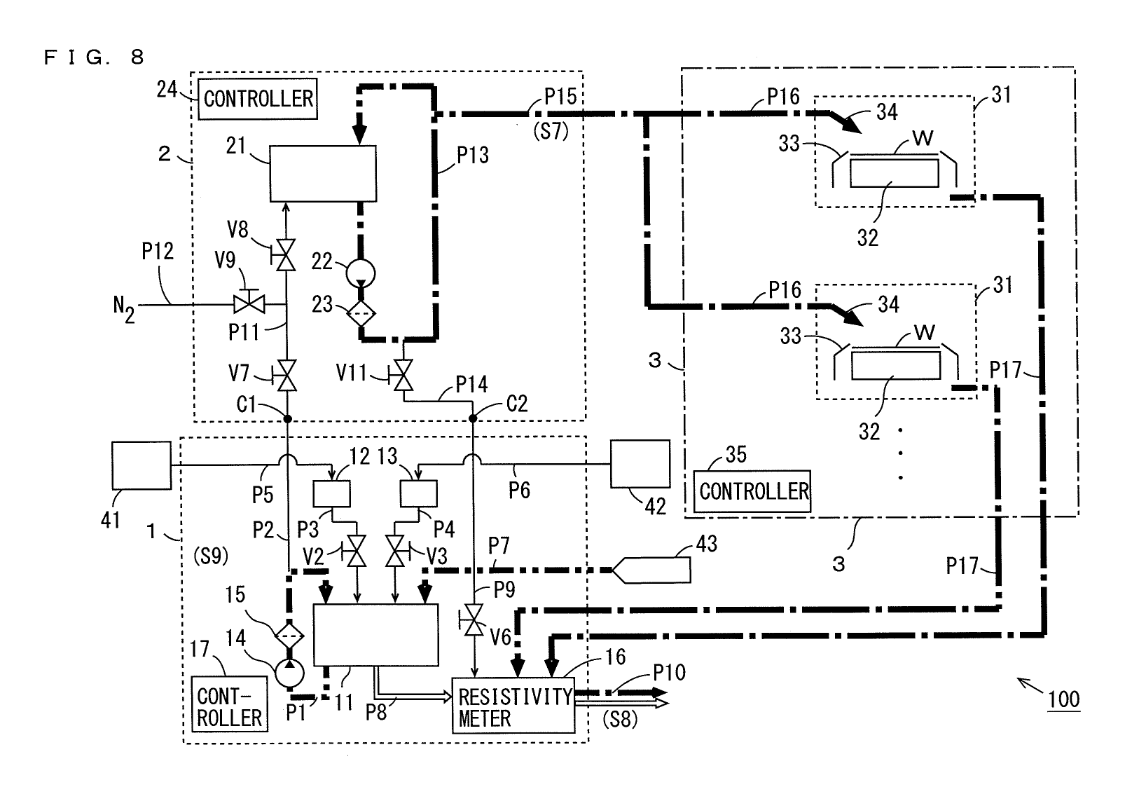

Then, the pipe cleaning is performed by control of the controller 24 and the controller 35 (step S7). In this case, the controller 24 opens the valve V12 of FIG. 1, and the controller 35 opens the valves V13, V14 of FIG. 1. Thus, as indicated by thick one-dot and dash arrows in FIG. 8, the second cleaning liquid is supplied from the pipe P13 to each processing unit 31 through the pipes P15, P16 and the nozzles 34. The second cleaning liquid in each processing unit 31 is discharged through the pipes P17, P10. Thus, the pipes P13, P15 to P17, the valves V12 to V14, and the nozzles 34 are cleaned by the second cleaning liquid.

Further, whether the resistivity of the second cleaning liquid is the predetermined value is determined by control of the controller 17 (step S8). In this case, the controller 17 measures the resistivity of the second cleaning liquid by the resistivity meter 16. In the case where the resistivity is not the predetermined value, it returns to the step S6, and the supply of the second cleaning liquid from the cleaning liquid tank 11 to the processing liquid tank 21 and the pipe cleaning by the second cleaning liquid are performed. In the case where the resistivity becomes the predetermined value, the controller 24 closes the valves V10, V12 of FIG. 1, and the controller 35 closes the valves V13, V14.

Concurrently with the pipe cleaning of the step S7, the third cleaning liquid is prepared by control of the controller 17 (step S9). In this case, the controller 17 opens the valves V1, V4, V5 of FIG. 1. Thus, as indicated by thick two-dots and dash arrows in FIG. 8, pure water is supplied from the pure water supply source 43 to the cleaning liquid tank 11 through the pipe P7 as the third cleaning liquid. As indicated by outlined arrows in FIG. 8, the second cleaning liquid in the cleaning liquid tank 11 is discharged through the pipes P8, P10. Further, the third cleaning liquid circulates through the pipe P1. As a result, the second cleaning liquid in the cleaning liquid tank 11, the pipe P1, the pump 14 and the filter 15 is replaced with the third cleaning liquid. Further, the controller 17 measures the resistivity of the third cleaning liquid by the resistivity meter 16. When the resistivity becomes a predetermined value, the controller 17 closes the valve V5 of FIG. 1, and stores the third cleaning liquid in the cleaning liquid tank 11. Thereafter, the controller 17 closes the valve V4.

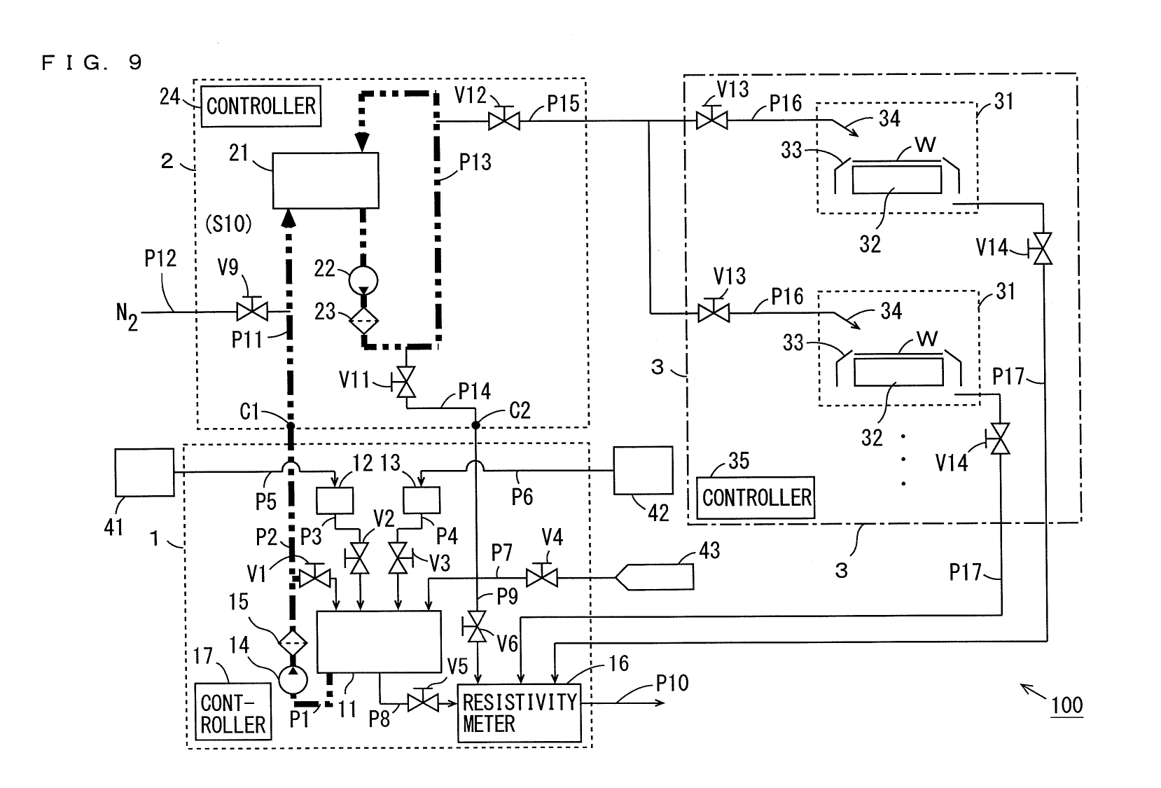

Then, the supply of the third cleaning liquid from the cleaning liquid tank 11 to the processing liquid tank 21 and cleaning of the cleaning liquid tank 21 are performed by control of the controller 24 (step S10). In this case, after the controller 17 closes the valve V1 of FIG. 1 to stop the return of the third cleaning liquid to the cleaning liquid tank 11, the controller 24 opens the valves V7, V8 of FIG. 1. Thus, as indicated by thick two-dots and dash arrows in FIG. 9, the third cleaning liquid is supplied from the pipe P1 to the processing liquid tank 21 through the pipe P11. Further, the controller 24 opens the valve V10 of FIG. 1. Thus, the third cleaning liquid circulates through the pipe P13, and the second cleaning liquid in the cleaning liquid tank 11, the pipe P13, the filter 15 and the pump 14 is cleaned away by the third cleaning liquid.

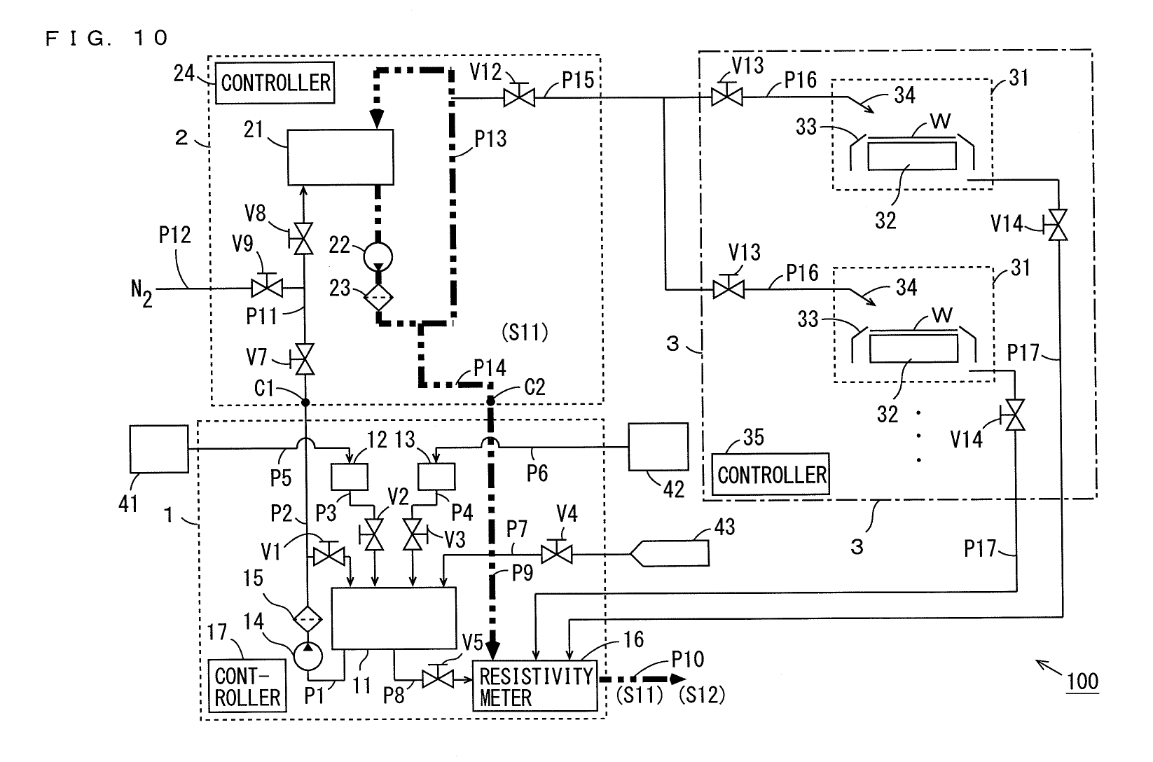

Further, whether the resistivity of the third cleaning liquid is the predetermined value is determined by control of the controller 17 and the controller 24 (step S11). In this case, the controller 17 opens the valve V6 of FIG. 1, and the controller 24 opens the valve V11 of FIG. 1. Thus, as indicated by thick two-dots and dash arrows in FIG. 10, the third cleaning liquid in the processing liquid tank 21 and the pipe P13 is discharged through the pipes P14, P9, P10. The controller 17 measures the resistivity of the third cleaning liquid by the resistivity meter 16. In the case where the resistivity is not the predetermined value, it returns to the step S10, and the supply of the third cleaning liquid from the cleaning liquid tank 11 to the processing liquid tank 21 and circulation of the third cleaning liquid are performed.

In the case where the resistivity becomes the predetermined value, the third cleaning liquid in the processing liquid tank 21, the pipes P13, P14, P9, P10 is discharged by control of the controller 24 and the controller 17 (step S12). After the discharge of the third cleaning liquid in the processing liquid tank 21 and the pipes P13, P14, P9, P10, the controller 24 closes the valves V6, V10, V11 of FIG. 1.

Inside of the processing liquid tank 21 can be sufficiently cleaned by the above-mentioned steps S9 to S12.

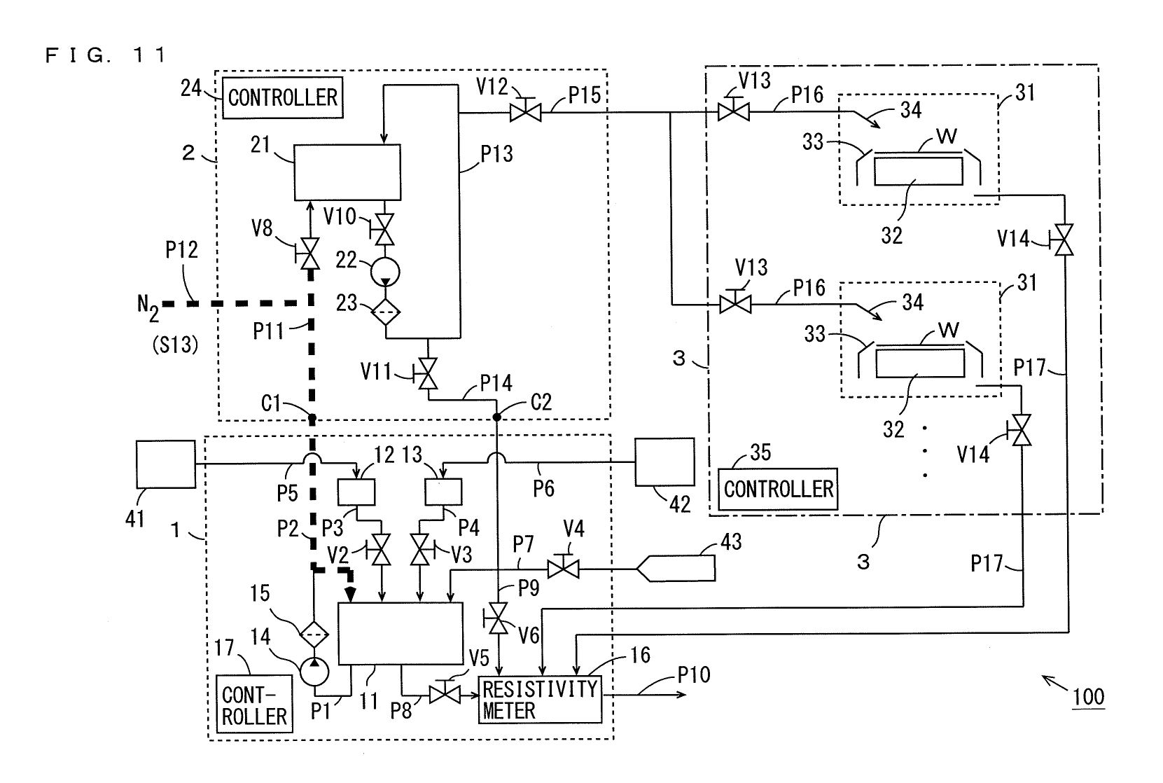

Thereafter, a nitrogen gas is sealed by control of the controller 24 (step S13). In this case, the controller 24 opens the valves V7, V9, and the controller 17 opens the valve V1. Thus, as indicated by a thick broken arrow in FIG. 11, a nitrogen gas is sealed in the pipes P11, P2, P1 and the cleaning liquid tank 11.

(3) Effects

In the substrate processing system 100 according to the present embodiment, concurrently with the cleaning of the pipes P13, P15 to P17 by the first cleaning liquid (step S4), the second cleaning liquid (step S5) can be prepared in the cleaning unit 1. Further, concurrently with the cleaning of the pipes P13, P15 to P17 by the second cleaning liquid (step S7), the third cleaning liquid (step S9) can be prepared in the cleaning unit 1. Therefore, a time period required for the cleaning of the pipes P13, P15 to P17 by the first cleaning liquid and the second cleaning liquid can be shortened. As a result, the pipes P13, P15 to P17 can be cleaned in a short period of time with the plurality of cleaning liquids.

Further, concurrently with the circulation of the first cleaning liquid and the cleaning preparation in the processing liquid supply unit 2 (step S3), the third cleaning liquid (step S9) can be also prepared in the cleaning unit 1. In this case, a time period required for the cleaning of the pipes P13, P15 to P17 by the first cleaning liquid and the second cleaning liquid can be further shortened.

Further, because the valves V7, V8 inserted into the pipe P11 are closed after the end of the supply of the first cleaning liquid from the cleaning unit 1 to the processing liquid tank 21, the preparation of the second cleaning liquid can be started in the cleaning unit 1 right after the end of the supply of the first cleaning liquid from the cleaning unit 1 to the processing liquid tank 21. Thus, the cleaning of the pipes P13, P15 to P17 by the first cleaning liquid and the second cleaning liquid can be performed in a shorter period of time.

Further, because a nitrogen gas is sealed in the cleaning liquid tank 11 of the cleaning unit 1 and the pipes P2, P11 after the cleaning of the pipes P13, P15 to P17 and the processing liquid tank 21, contamination in the pipes P2, P11 and the cleaning liquid tank 11 due to entry of particles or the like is prevented.

Further, the cleaning unit 1 is connectable to and disconnectable from the processing liquid supply unit 2, so that the cleaning unit 1 can be disconnected from the processing liquid supply unit 2 after the end of the cleaning of the pipes P13, P15 to P17 and can be connected to another processing liquid supply unit 2. Thus, the pipes of the plurality of processing liquid supply units 2 and plurality of substrate processing apparatuses 3 can be sequentially cleaned by the single cleaning unit 1. Further, during the processing of the substrate W by the substrate processing apparatus 3, because the cleaning unit 1 can be disconnected from the processing liquid supply unit 2, the size of the substrate processing system 100 during the operation of the substrate processing apparatus 3 is inhibited from increasing.

### [2] Second Embodiment

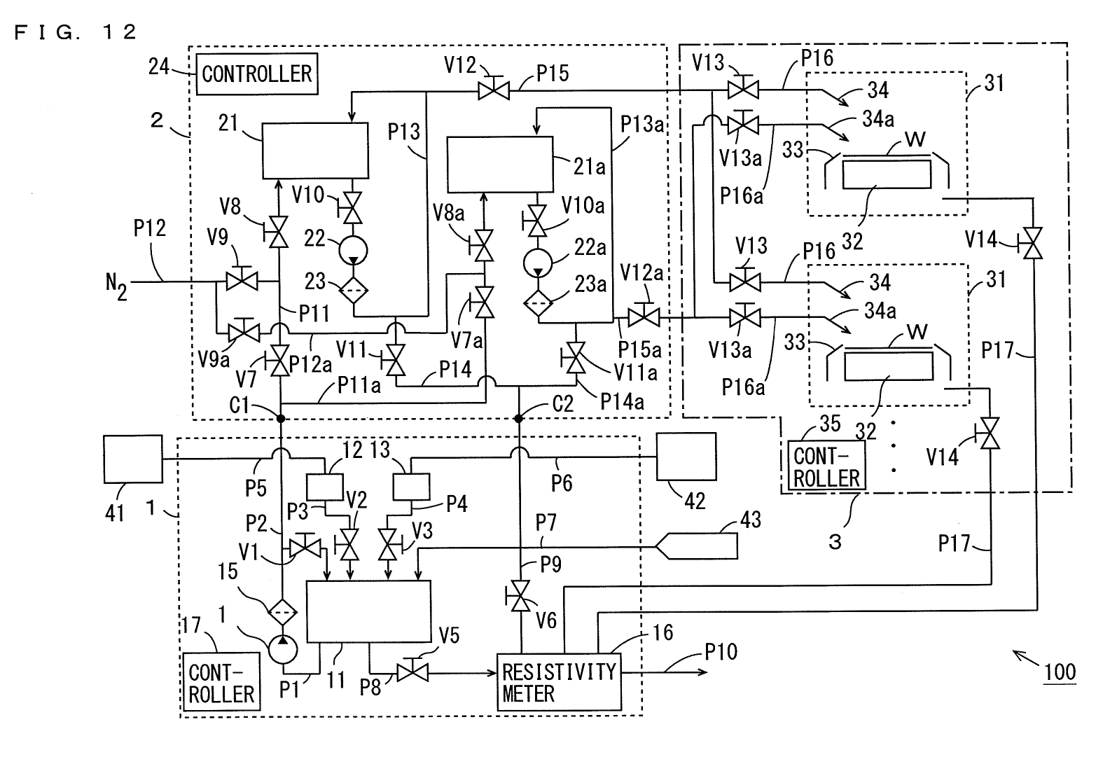

FIG. 12 is a schematic diagram showing the configuration of a substrate processing system according to the second embodiment of the present invention. The configuration and operation of the substrate processing system 100 according to the second embodiment are similar to the configuration and operation of the substrate processing system 100 according to the first embodiment except for the following points.

As shown in FIG. 12, in the present embodiment, a processing liquid tank 21a is provided in the processing liquid supply unit 2 in addition to the processing liquid tank 21 of FIG. 1. A pipe P11a is provided to branch from a portion of the pipe P11 between the valve V7 and the connector C1.

The pipe P11a is connected to a liquid inlet port of the processing liquid tank 21a. Valves V7a, V8a are inserted into the pipe P11a. A pipe P12a is provided to branch from a portion of the pipe P12 at upstream of the valve V9. The pipe P12a is connected to a portion of the pipe P11a between the valves V7a, V8a. A valve V9a is inserted into the pipe P12a. A nitrogen gas can be supplied to the pipe P11a through the pipe P12a.

A pipe P13a for liquid circulation is connected between a liquid inlet port and a liquid outlet port of the processing liquid tank 21a. A valve V10a, a pump 22a and a filter 23a are inserted into the pipe P13a. A pipe P14a is provided to branch from the pipe P13a. A valve Vila is inserted into the pipe P14a. The pipe P14a is connected to the connector C2. Further, a pipe P15a is provided to branch from the pipe P13a. A valve V12a is inserted into the pipe P15a. A plurality of pipes P16a branch from the pipe P15a.

The controller 24 controls operations of the processing liquid supply unit 2 such as opening and closing of the valves V7 to V12, V7a to V12a and operations of the pumps 22, 22a.

During processing of the substrate in the substrate processing apparatus 3, a processing liquid is stored in the processing liquid tanks 21, 21a. Different types of processing liquids from each other may be stored in the processing liquid tanks 21, 21a. Alternatively, processing liquids having the same component and different concentrations from each other may be stored in the processing liquid tanks 21, 21a.

Each processing unit 31 in the substrate processing apparatus 3 includes a nozzle 34a in addition to the substrate holder 32, the cup 33 and the nozzle 34. The nozzle 34a is connected to the pipe P16a. A valve V13a is inserted into each pipe P16a. The controller 35 controls operations of the substrate processing apparatus 3 such as opening and closing of the valves V13, V13a, V14.

In the substrate processing system 100 in FIG. 12, when the valves V7, V8, V7a, V8a are opened, the cleaning liquid is simultaneously supplied from the cleaning unit 1 to the two processing liquid tanks 21, 21a. Further, with the cleaning liquid being stored in the two processing liquid tanks 21, 21a, when the valves V10, V10a, V12, V12a are opened, the cleaning liquid in the processing liquid tanks 21, 21a is supplied to each processing unit 31 through the pipes P15, P15a, P16, P16a and the nozzles 34, 34a. Thus, the two processing liquid tanks 21, 21a of the processing liquid supply unit 2 and the pipes P11 to P16, P11a to P16a can be simultaneously cleaned.

Further, different cleaning liquids can be respectively supplied from the cleaning unit 1 to the processing liquid tanks 21, 21a of the processing liquid supply unit 2. In this case, the cleaning liquid can be supplied from the cleaning unit 1 to the processing liquid tank 21 by opening of the valves V7, V8. Further, the cleaning liquid can be supplied from the cleaning unit 1 to the processing liquid tank 21a by opening of the valves V7a, V8a. For example, after the SC1 is supplied to the processing liquid tank 21 as the first cleaning liquid, pure water is supplied to the processing liquid tank 21 as the second cleaning liquid. Thereafter, after the SC2 is supplied to the processing liquid tank 21a as the first cleaning liquid, pure water is supplied to the processing liquid tank 21a as the second cleaning liquid.

In this case, pure water can be prepared in the cleaning unit 1 concurrently with the pipe cleaning by the SC1, the SC2 can be prepared in the cleaning unit 1 concurrently with the pipe cleaning by pure water, and pure water can be prepared concurrently with the pipe cleaning by the SC2. Thus, a time period required for cleaning of the processing liquid tank 21 and pipes P13, P15 to P17 by the SC1 and pure water can be shortened, and a time period required for cleaning of the processing liquid tank 21a and the pipes P13a, P15a to P17a by the SC2 and pure water can be shortened.

### [3] Third Embodiment

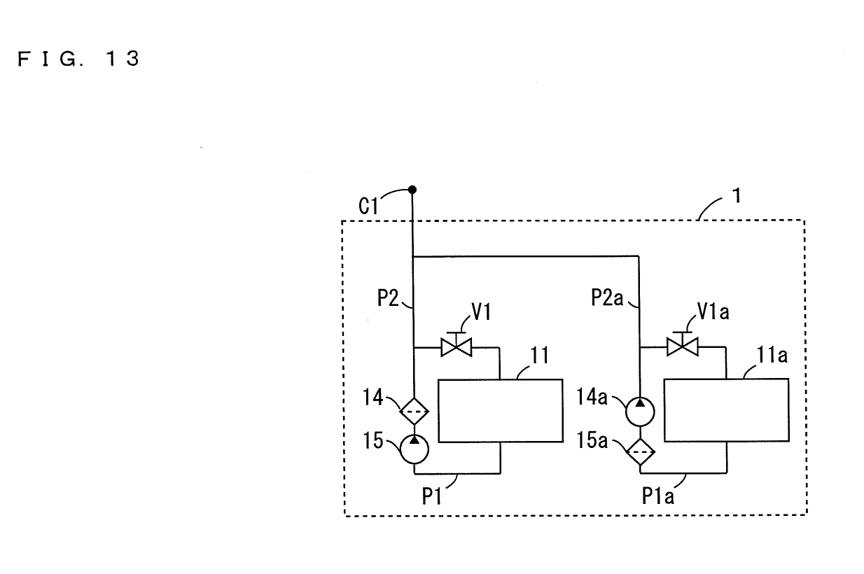

A substrate processing system according to the third embodiment has the same configuration as the substrate processing system 100 according to the first embodiment except for the configuration of a cleaning unit 1. FIG. 13 is a schematic diagram showing the configuration of a main part of the cleaning unit in the third embodiment of the present invention.

As shown in FIG. 13, the cleaning unit 1 in the present embodiment includes a cleaning liquid tank 11a in addition to the cleaning liquid tank 11. A pipe P1a for liquid circulation is connected to the cleaning liquid tank 11a. A valve V1a, a pump 14a and a filter 15a are inserted into the pipe P1a. A pipe P2a is provided to branch from the pipe P1a. The pipe P2a is connected to the pipe P2.

In FIG. 13, the weighing tanks 12, 13, the pipes P5 to P10, the valves V4 to V6, the resistivity meter 16 and the controller 17 of FIG. 1 are not shown. Further, the weighing tanks, the valves and the pipes connected to the cleaning liquid tank 11a are not shown either.

In the cleaning unit 1 of FIG. 13, different types of cleaning liquids from each other or cleaning liquids having different concentrations from each other can be stored in the cleaning liquid tanks 11, 11a. For example, the SC1 is used as the first cleaning liquid, pure water is used as the second cleaning liquid, the SC2 is used as the third cleaning liquid, and pure water is used as the fourth cleaning liquid. In this case, the second cleaning liquid can be prepared in the cleaning liquid tank 11 concurrently with the pipe cleaning by the first cleaning liquid. Further, the fourth cleaning liquid can be prepared in the cleaning liquid tank 11a concurrently with the pipe cleaning by the third cleaning liquid. Therefore, the pipes can be cleaned in a short period of time with the plurality of cleaning liquids.

### [4] Substrate Processing System Including Another Example of Cleaning Unit

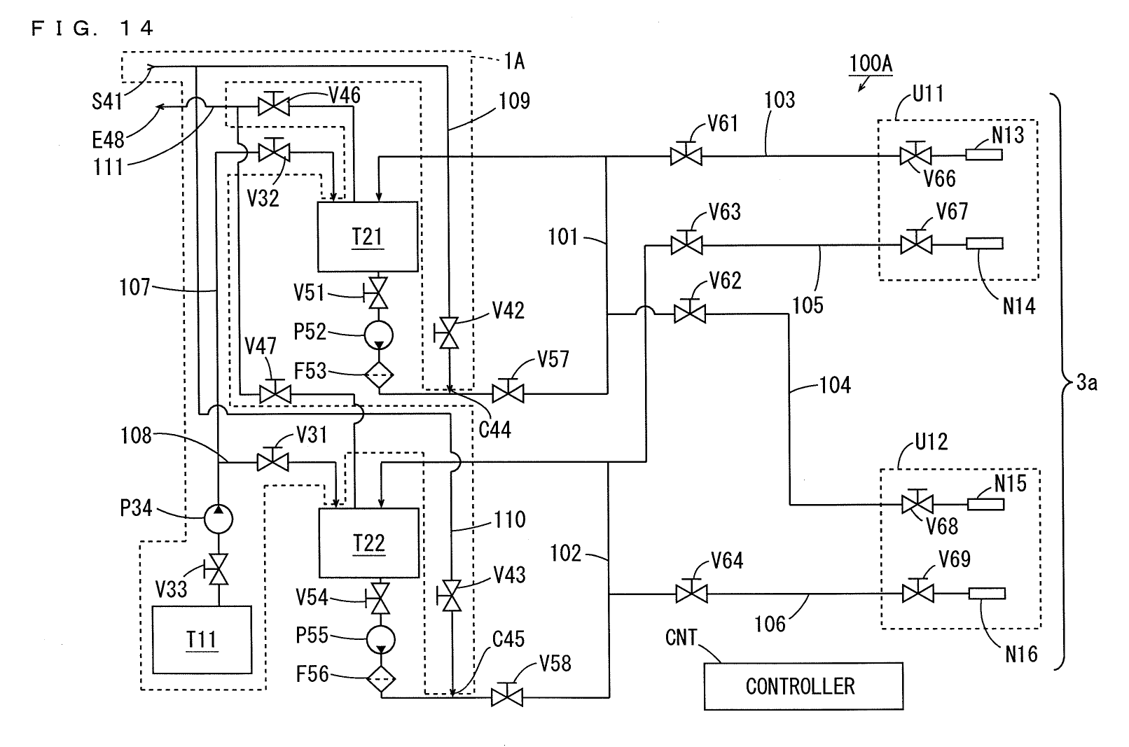

FIG. 14 is a schematic diagram showing the configuration of the substrate processing system including another example of the cleaning unit. The substrate processing system 100a includes a substrate processing apparatus 3a, a first processing liquid tank T21, a second processing liquid tank T22, a processing liquid supply path (a processing liquid supply mechanism) and a cleaning unit 1A.

While the cleaning unit 1A of the substrate processing system 100a has the configuration of being attachable to and detachable from the substrate processing apparatus 3a, the cleaning unit 1A may be provided inside of the substrate processing apparatus 3a. Thus, pipes of both are integrally shown in FIG. 14. The substrate processing apparatus 3a may include the first processing liquid tank T21, the second processing liquid tank T22 and the processing liquid supply path.

The substrate processing apparatus 3a includes first and second processing chambers (processing units) U11, U12. In the first and second processing chambers U11, U12, a processing liquid is supplied to a substrate such as a semiconductor wafer held and rotated by a spin chuck (a substrate holder that is not shown). Thus, the substrate is processed. The first processing liquid tank T21 stores an acid processing liquid such as HF. The second processing liquid tank T22 stores an alkaline processing liquid such as the SC1. The processing liquid supply path supplies the processing liquid from the first processing liquid tank T21 and the second processing liquid tank T22 to the first and second processing chambers U11, U12 by the configuration shown below.

A circulation path 101 for an acid processing liquid is connected to the first processing liquid tank T21. A valve V51, a pump P52, a filter F53 and a valve V57 are provided at the circulation path 101. The acid processing liquid is sent from the first processing liquid tank T21, and then returned to the first processing liquid tank T21 through the circulation path 101. The circulation path 101 is connected to a discharge path 103 for an acid processing liquid and a discharge path 104 for an acid processing liquid. The discharge path 103 is connected to a nozzle N13 in the first processing chamber U11 through valves V61, V66. The discharge path 104 is connected to a nozzle N15 in the second processing chamber U12 through valves V62, V68.

A circulation path 102 for an alkaline processing liquid is connected to the second processing liquid tank T22. A valve V54, a pump P55, a filter F56 and a valve V58 are provided at the circulation path 102. The alkaline processing liquid is sent from the second processing liquid tank T22, and then returned to the second processing liquid tank T22 through the circulation path 102. The circulation path 102 is connected to a discharge path 105 for an alkaline processing liquid and a discharge path 106 for an alkaline processing liquid. The discharge path 105 is connected to a nozzle N14 in the first processing chamber U11 through valves V63, V67. The discharge path 106 is connected to a nozzle N16 in the second processing chamber U12 through valves V64, V69.

The first processing liquid tank T21 is connected to a vent pipe 111 through a valve V46. The second processing liquid tank T22 is connected to the vent pipe 111 through a valve V47. The vent pipe 111 is connected to an air discharger E48.

The valve V46 is normally closed. When the inner pressure of the first processing liquid tank T21 becomes a predetermined value or more due to the supply of a nitrogen gas, described below, the valve V46 is opened and part of the gas in the first processing liquid tank T21 is released to the outside from the air discharger E48 through the vent pipe 111. Similarly, the valve V47 is normally closed. When the inner pressure of the second processing liquid tank T22 becomes a predetermined value or more due to the supply of a nitrogen gas, described below, the valve V47 is opened and part of the gas in the second processing liquid tank T22 is released to the outside from the air discharger E48 through the vent pipe 111.

In this substrate processing system 100a, the pump P52 is driven with a valve V51 and a valve V57 being open, so that the acid processing liquid in the first processing liquid tank T21 circulates through the circulation path 101. That is, the acid processing liquid stored in the first processing liquid tank T21 is sent from the first processing liquid tank T21 by the pump P52, and then moves through the circulation path 101 to be returned to the first processing liquid tank T21. In this state, in the case where the valve V61 and the valve V66 are opened, the acid processing liquid circulating through the circulation path 101 is supplied from the nozzle N13 to the rotating substrate in the first processing chamber U11 through the discharge path 103. Further, in the case where the valve V62 and the valve V68 are opened, the acid processing liquid is supplied from the nozzle N15 to the rotating substrate in the second processing chamber U12 through the discharge path 104. These acid processing liquids are collected in the first processing liquid tank T21 through a collection path (not shown) from the first processing chamber U11 or the second processing chamber U12. The acid processing liquid used for the processing of the substrate may be discarded.

On the one hand, the pump P55 is driven with the valve V54 and the valve V58 being opened, so that the alkaline processing liquid in the second processing liquid tank T22 circulates through the circulation path 102. That is, the alkaline processing liquid stored in the second processing liquid tank T22 is sent from the second processing liquid tank T22 by the pump P55, and then moves through the circulation path 102 to be returned to the second processing liquid tank T22. In this state, in the case where the valve V63 and the valve V67 are opened, the alkaline processing liquid is supplied from the nozzle N14 to the rotating substrate in the first processing chamber U11 through the discharge path 105. Further, in the case where the valve V64 and the valve V69 are opened, the alkaline processing liquid is supplied from the nozzle N16 to the rotating substrate in the second processing chamber U12 through the discharge path 106. These alkaline processing liquids are collected in the second processing liquid tank T22 from the first processing chamber U11 or the second processing chamber U12 through a collection path (not shown). The alkaline processing liquid used for processing of the substrate may be discarded.

The processing liquid supply path includes the circulation paths 101, 102 and the discharge paths 103 to 106. In the present example, valves V31 to V33, V42, V43 and the valves V46, V47, V51, V54, V57, V58, V61 to V69 are opening closing valves. While the substrate processing apparatus 3a of the present example has the two processing chambers (the first and second processing chambers U11, U12), the number of the processing chambers is not limited to two. The number of the processing chambers may be about four to twelve. For example, in the case where the substrate processing apparatus 3a has eight processing chambers, eight discharge paths for an acid processing liquid and eight discharge paths for an alkaline processing liquid are required. Further, in the substrate processing system 100a of the present example, the substrate is processed by two types of acid and alkaline processing liquids. However, the larger number of types of processing liquids may be supplied to the substrate, and the substrate may be processed by these processing liquids.

The cleaning unit 1A of the substrate processing system 100a includes a cleaning liquid tank T11 that stores a cleaning liquid. The cleaning liquid in the cleaning liquid tank T11 is sent from the cleaning liquid tank T11 through the valve V33 and a pump P34, and then supplied to the first processing liquid tank T21 through a cleaning liquid supply path 107 having the valve V32 while being supplied to the second processing liquid tank T22 through a cleaning liquid supply path 108 having the valve V31.

Further, the cleaning unit 1A has a supplier S41 for a nitrogen gas used as an inert gas. The supplier S41 is connected to the circulation path 101 at a connector C44 through a nitrogen gas supply path 109 having the valve V42. Therefore, as described below, a nitrogen gas can be mixed in the cleaning liquid circulating through the circulation path 101 from the connector C44.

Similarly, the supplier S41 is connected to the circulation path 102 at a connector C45 through a nitrogen gas supply path 110 having the valve V43. Therefore, as described below, a nitrogen gas can be mixed in the cleaning liquid circulating through the circulation path 102 from the connector C45.

Further, the substrate processing system 100a has a controller CNT that integrally controls the cleaning unit 1A and the substrate processing apparatus 3a. The controller CNT controls the above-mentioned valves V31 to V33, the supplier S41 for a nitrogen gas, the valves V42, V43, V46, V47, V51, V54, V57, V58, V61 to V64, V66 to V69, the pumps P34, P52, P55 and the like to perform cleaning processing of the pipes that constitute the processing liquid supply path of the substrate processing system 100a, described below.

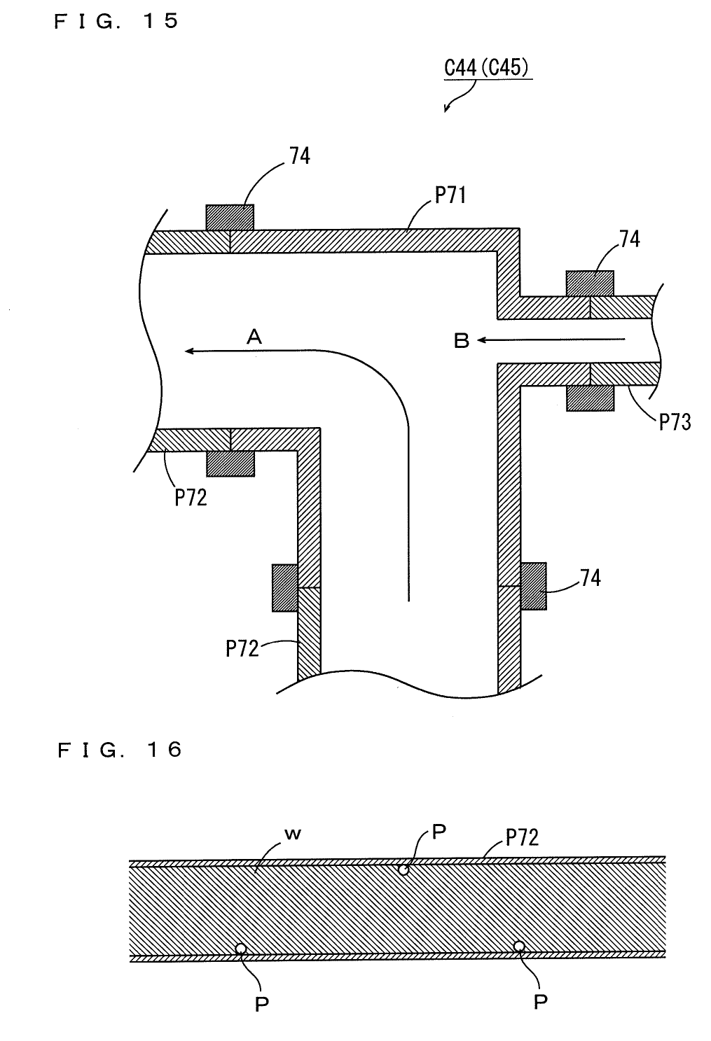

FIG. 15 is an explanatory view showing a nitrogen gas being mixed in the circulating cleaning liquid at each connector C44, C45.

A T-shape pipe P71 having a small diameter portion and a large diameter portion is used at each connector C44, C45. The large diameter portion of the T-shape pipe P71 is connected to a pipe P72 by a nut 74. The pipe P72 constitutes the circulation path 101 for an acid processing liquid and the circulation path 102 for an alkaline processing liquid. The small diameter portion of the T-shape pipe P71 is connected to a pipe P73 by the nut 74. The pipe P73 constitutes the nitrogen gas supply path 109 or the nitrogen gas supply path 110. In FIG. 15, an acid or alkaline processing liquid that moves inside of the pipe P72 (the circulation paths 101, 102) is indicated by a character A, and a nitrogen gas that moves inside of the pipe P73 (the nitrogen gas supply path 109 or the nitrogen gas supply path 110) is indicated by a character B. The pipe P73 has an inner diameter that is smaller than the pipe P72. At each connector C44, C45, a nitrogen gas is supplied from the pipe P73 having an inner diameter smaller than the pipe P72 that constitutes the circulation path 101 or the circulation path 102 in the same direction as a flow of the cleaning liquid circulating through the pipe P72. Therefore, the nitrogen gas B can be supplied to the cleaning liquid A circulating through the pipe P72 with no occurrence of a reverse flow and a pressure loss. Thus, a circulation speed of the cleaning liquid circulating through the pipe P72 can be increased.

In the case where the processing liquid supply path of the substrate processing system 100a is cleaned by the cleaning unit 1A of the substrate processing system 100a having the above-mentioned configuration, a necessary amount of the cleaning liquid is supplied from the cleaning liquid tank T11 of the cleaning unit 1A to the first processing liquid tank T21 and the second processing liquid tank T22. That is, with all valves being closed, the controller CNT opens the valve V33 and drives the pump P34. At the same time, the controller CNT supplies the cleaning liquid to the first processing liquid tank T21 by opening the valve V32, and supplies the cleaning liquid to the second processing liquid tank T22 by opening the valve V31. When a necessary amount of the cleaning liquid is supplied to the first processing liquid tank T21 and the second processing liquid tank T22, the controller CNT closes the valves V31, V32, V33 and stops driving the pump P34.

Then, the controller CNT opens the valve V51 and the valve V57, and drives the pump P52 to circulate the cleaning liquid through the circulation path 101 for an acid processing liquid. Further, the controller CNT opens the valve V42 with the cleaning liquid circulating, and supplies a nitrogen gas from the connector C44 to the cleaning liquid circulating through the circulation path 101. Thus, a flow speed of the cleaning liquid circulating through the circulation path 101 increases due to the effect of a nitrogen gas. A supply amount of a nitrogen gas per unit time at this time (7 to 28 liters per minute, for example) is a supply amount of the cleaning liquid supplied to the circulation path 101 per unit time (7 liters per minute, for example) or more.

Further, the controller CNT opens the valve V54 and V58, and drives the pump P55 to circulate the cleaning liquid through the circulation path 102 for an alkaline processing liquid. Further, the controller CNT opens the valve V43 with the cleaning liquid circulating, and supplies a nitrogen gas from the connector C45 to the cleaning liquid circulating through the circulation path 102. Thus, a flow speed of the cleaning liquid circulating through the circulation path 102 increases due to the effect of a nitrogen gas. A supply amount of a nitrogen gas per unit time (7 to 28 liters per minute, for example) at this time is also a supply amount of the cleaning liquid supplied to the circulation path 102 per unit time (7 liters per minute, for example) or more.

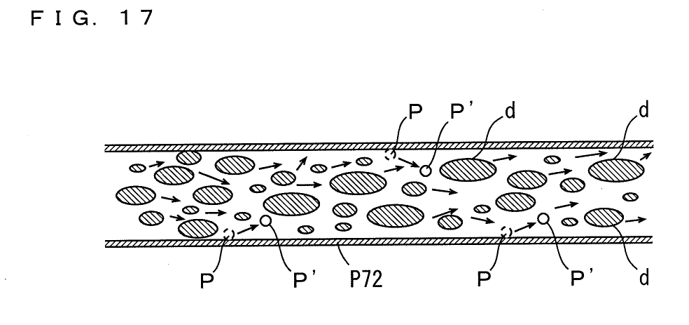

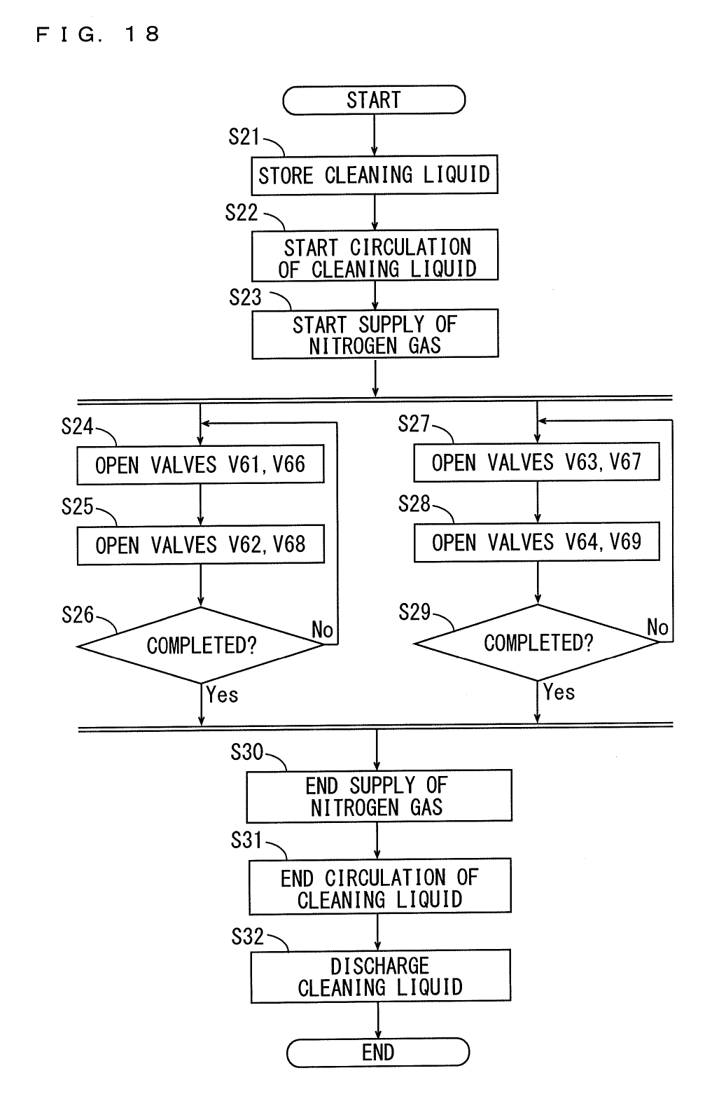

FIG. 16 is a schematic diagram showing the cleaning liquid flowing through the pipe P72 in the case where a nitrogen gas is not supplied. FIG. 17 is a schematic diagram showing the cleaning liquid flowing through the pipe P72 in the case where a nitrogen gas is supplied.

As shown in the example of FIG. 16, in the case where a nitrogen gas is not supplied, the cleaning liquid w moves at a low speed while adhering to an inner wall of the pipe P72. In this case, a large physical force is not exerted on particles P adhering to the inner wall of the pipe P72, so that these particles P cannot be efficiently removed.

On the one hand, as described above with reference to FIG. 15, at the connector C44 (C45), a nitrogen gas having a volume of a supply amount of the cleaning liquid supplied to the circulation path 101 (102) per unit time or more is supplied to the cleaning liquid flowing through the pipe P72. Thus, at the connector C44 (C45), the cleaning liquid is broken into a plurality of droplets d (FIG. 17) smaller than an inner diameter of the pipe P72, and accelerates largely. As shown in FIG. 17, the plurality of droplets d move at a high speed while repeatedly colliding with the inner wall of the pipe P72 at downstream of the connector C44 (C45). The droplets d of the cleaning liquid exert a large physical force on the particles P adhering to the inner wall of the pipe P72 every time the droplets d collide with the pipe P72. Thus, the particles P are stripped from the inner wall of the pipe P72 to be removed. In FIG. 17, removed particles are denoted with a character P′.

In the case of the example of FIG. 16, a large physical force cannot be exerted on minute particles adhering to irregular portions, joint portions or the like of the inner wall of the pipe P72, and these particles sometimes cannot be removed sufficiently. In contrast, in the cleaning unit 1A of the present example, the cleaning liquid is broken into droplets that are smaller than the inner diameter of the pipe P72 and moves at a high speed by the nitrogen gas supplied from the connector C44 and the connector C45. Therefore, a large physical force can be exerted on minute particles adhering to the irregular portions, the joint portions or the like of the inner wall of the pipe P72. Thus, minute particles adhering to the inside of the pipe P72 can be removed with high efficiency.

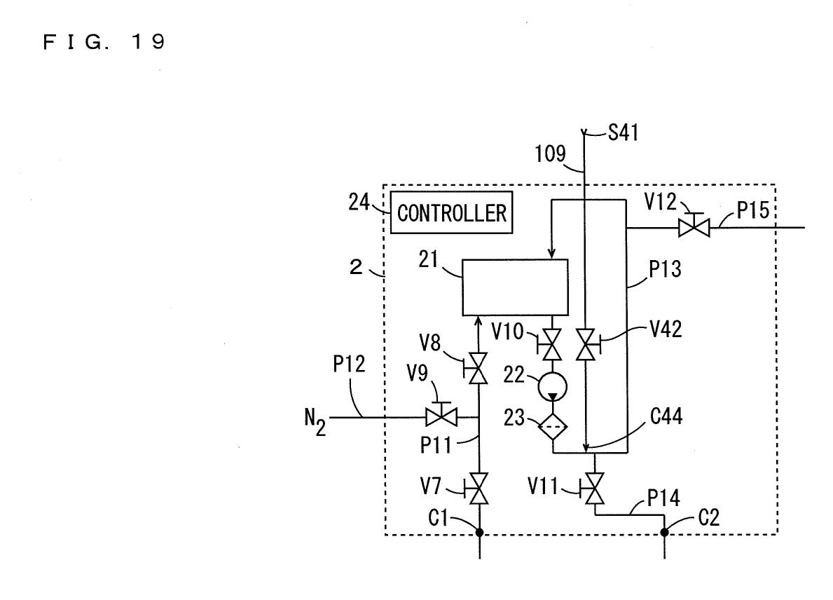

FIG. 18 is a flow chart showing a cleaning procedure of the pipes of the substrate processing system 100a using the cleaning unit 1A and the substrate processing apparatus 3a of FIG. 14. The cleaning procedure of the pipes of the substrate processing system 100a will be described with reference to FIGS. 14 and 18.

First, as described above, the controller CNT stores a predetermined amount of the cleaning liquid supplied from the cleaning liquid tank T11 in the first processing liquid tank T21 and the second processing liquid tank T22 by opening the valves V31 to V33 and operating the pump P34 with the valves V51, V54 being closed (step S21).

Then, the controller CNT starts to circulate the cleaning liquid through the circulation path 101 for an acid processing liquid by opening the valves V51, V57 with the valves V61, V62 being closed and starting an operation of the pump P52. At the same time, the controller CNT starts to circulate the cleaning liquid through the circulation path 102 for an alkaline processing liquid by opening the valves V54, V58 with the valves V63, V64 being closed and starting an operation of the pump P55 (step S22).

When the inside of the circulation path 101 is filled with the cleaning liquid, the controller CNT continuously opens the valve V42 to start the supply of a nitrogen gas to the circulation path 101. Similarly, when the inside of the circulation path 102 is filled with the cleaning liquid, the controller CNT continuously opens the valve V43 to start the supply of a nitrogen gas to the circulation path 102 (step S23). As described above, the inner walls of the circulation paths 101, 102 start to be efficiently cleaned by a plurality of droplets of the cleaning liquid.

The inner pressure of the nitrogen gas in the circulation path 101 (102) including the processing liquid tank T21 (T22) increases due to the supply of a nitrogen gas at the connector C44 (C45). However, the controller CNT opens and closes the valve V46 (V47) at appropriate time points, so that an excess amount of the nitrogen gas is vented from the discharger E48. Therefore, the inner pressure of the nitrogen gas in the circulation path 101 (102) is maintained constant. If the inner pressure of the nitrogen gas becomes too high, the supply of a nitrogen gas from each connector C44, C45 becomes difficult. However, in the present example, the controller CNT performs ventilation by controlling opening and closing of the valves V46, V47 at appropriate time points, so that a nitrogen gas can be continuously supplied from the connectors C44, C45 to the circulation paths 101, 102.

When the cleaning liquid sufficiently circulates through the circulation path 101 or the circulation path 102 together with a nitrogen gas, the controller CNT lets the cleaning liquid be discharged from the nozzle N13 by opening the valves V61, V66 (step S24). Thus, a first discharge path cleaning operation of cleaning the discharge path 103 for an acid processing liquid connected to the nozzle N13 in the first processing chamber U11 is performed.

Then, the controller CNT lets the cleaning liquid be discharged from the nozzle N15 by opening the valves V62, V68 (step S25). Thus, a second discharge path cleaning operation of cleaning the discharge path 104 for an acid processing liquid connected to the nozzle N15 in the second processing chamber U12 is performed.

If the valves V61, V62, V66, V68 are continuously opened, the cleaning liquid and a nitrogen gas are continuously discharged from the nozzle N13 and the nozzle N15. In this case, the inner pressure of the nitrogen gas in each of the circulation path 101 and the discharge paths 103, 104 may decrease.

Further, even if the valve V61 (V66) and the valve V62 (V68) are opened and closed respectively and intermittently, in the case where time points at which the cleaning liquid and the like are discharged from the nozzle N13 and the nozzle N15 coincide with each other, the inner pressure of the nitrogen gas in each of the circulation path 101 and the discharge paths 103, 104 may decrease. In this case, a flow speed of the droplets of the cleaning liquid flowing through each of the circulation path 101 and the discharge paths 103, 104 decreases, so that the sufficient cleaning effect is not acquired. This phenomenon becomes significant as the number of the discharge paths 103, 104 connected to the same circulation path 101 increases.

In the present example, time points at which the valves V61, V62, V66, V68 are opened and closed are controlled such that the cleaning liquid and the like are discharged intermittently from the nozzle N13 and the nozzle N15. Also, the time points at which the valves V61, V62, V66, V68 are opened and closed are controlled such that time points at which the cleaning liquid or the like are discharged from the nozzle N13 and the nozzle N15 do not coincide with each other. Therefore, a decrease in inner pressure of the nitrogen gas in each of the circulation path 101 and the discharge paths 103, 104 and a decrease in flow speed of the droplets of the cleaning liquid can be effectively prevented.

The controller CNT repeatedly performs the step S24 and the step S25 until cleaning of the inner walls of the discharge path 103 and the discharge path 104 is completed (step S26).

Concurrently with the steps S24 to S26, the steps S27 to S29 are performed. That is, the controller CNT lets the cleaning liquid be discharged from the nozzle N14 by opening the valves V63, V67 (step S27). Thus, a third discharge path cleaning operation of cleaning the discharge path 105 for an alkaline processing liquid connected to the nozzle N14 in the first processing chamber U11 is performed.

Then, the controller CNT lets the cleaning liquid be discharged from the nozzle N16 by opening the valves V64, V69 (step S28). Thus, a fourth discharge path cleaning operation of cleaning the discharge path 106 for an alkaline processing liquid connected to the nozzle N16 in the second processing chamber U12 is performed.

The controller CNT repeatedly performs the step S27 and the step S28 until cleaning of the inner walls of the discharge path 105 and the discharge path 106 is completed (step S29).

In this case, time points at which the valves V63, V64, V67, V69 are opened and closed are controlled such that the nozzle N14 and the nozzle N16 discharge the cleaning liquid and the like intermittently. Further, time points at which the cleaning liquid and the like are discharged from the nozzle N14 and the nozzle N16 are made different from each other. These control operations are based on the same reason as the control of the discharge operation of the cleaning liquid and the like from the nozzle N13 and the nozzle N15.

Here, there is a case where it is desired that the cleaning liquid that has cleaned the acid processing liquid supply paths (the circulation path 101 and the discharge paths 103, 104) and the cleaning liquid that has cleaned the alkaline processing liquid supply paths (the circulation path 102 and the discharge paths 105, 106) are collected separately. In this case, a time point for the first discharge path cleaning operation (step S24) and a time point for the third discharge path cleaning operation (step S27) may be made different from each other, and a time point for the second discharge path cleaning operation (step S25) and a time point for the fourth discharge path cleaning operation (step S28) may be made different from each other.

It is necessary to continuously supply an amount of a nitrogen gas, which is sufficiently larger than the supply amount of the cleaning liquid supplied to the pipe P72 per unit time, to the pipe P72 that constitutes the circulation path 101 or the circulation path 102 such that a sufficient amount of a nitrogen gas is discharged from each nozzle N13, N14, N15, N16 together with the cleaning liquid. Therefore, the supply amount of the nitrogen gas supplied to the pipe P72 per unit time is preferably set to several times of the supply amount of the cleaning liquid supplied to the pipe P72 per unit time or more. The supply amount indicates a volume of each of the nitrogen gas and the cleaning liquid under atmospheric pressure.

When the above-mentioned operation ends, the controller CNT closes the valves V42, V43 to end the supply of a nitrogen gas (step S30). Next, the controller CNT stops the operations of the pumps P52, P55 to end circulation of the cleaning liquid through the circulation paths 101, 102 (step S31). Finally, the controller CNT lets the cleaning liquid be discharged from the first processing liquid tank T21 and the second processing liquid tank T22, and closes all the valves to end the cleaning operation (step S32). An operator removes the cleaning unit 1A of the substrate processing system 100a from the substrate processing apparatus 3a as needed.

While the substrate processing system 100a that processes the substrate using two types of acid and alkaline processing liquids is cleaned in the present example, a substrate processing system that processes the substrate using a single processing liquid may be cleaned by the cleaning unit 1A of the present example. Further, a substrate processing system that processes the substrate using three or more types of processing liquids may be cleaned by the cleaning unit 1A of the present example.

### [5] Fourth Embodiment

In a substrate processing system according to the fourth embodiment, part of the configuration of the cleaning unit 1A of FIGS. 14 to 18 is applied to the processing liquid supply unit 2 of the substrate processing system 100 according to the first embodiment (FIG. 1). FIG. 19 is a schematic diagram showing the configuration of a main part of a processing liquid supply unit in the fourth embodiment.

As shown in FIG. 19, the supplier S41 for a nitrogen gas used as an inert gas is provided in the processing liquid supply unit 2. The supplier S41 is connected to the pipe P13 at the connector C44 through the nitrogen gas supply path 109 having the valve V42. In this case, the pipe P13 of FIG. 1 constitutes the circulation path 101 of FIG. 14, and the pipes P15, P16 of FIG. 1 constitute the discharge paths 103, 104 of FIG. 14. Further, the valves V12, V13 of FIG. 1 correspond to the valves V61, V66 and the valves V62, V68 of FIG. 14.

Such a configuration enables a nitrogen gas to be mixed in the first cleaning liquid circulating through the pipe P13 in the steps S3, S4 of FIG. 2 from the connector C44. Further, a nitrogen gas can be mixed in the second cleaning liquid circulating through the pipe P13 in the steps S6, S7 of FIG. 2 from the connector C44. Further, a nitrogen gas can be mixed in the third cleaning liquid circulating through the pipe P13 in the steps S10, S11 of FIG. 2 from the connector C44. Thus, minute particles adhering to the inner walls of the pipes P13, P15, P16, P14, P9 (FIG. 1) can be removed with high efficiency.

### [6] Fifth Embodiment

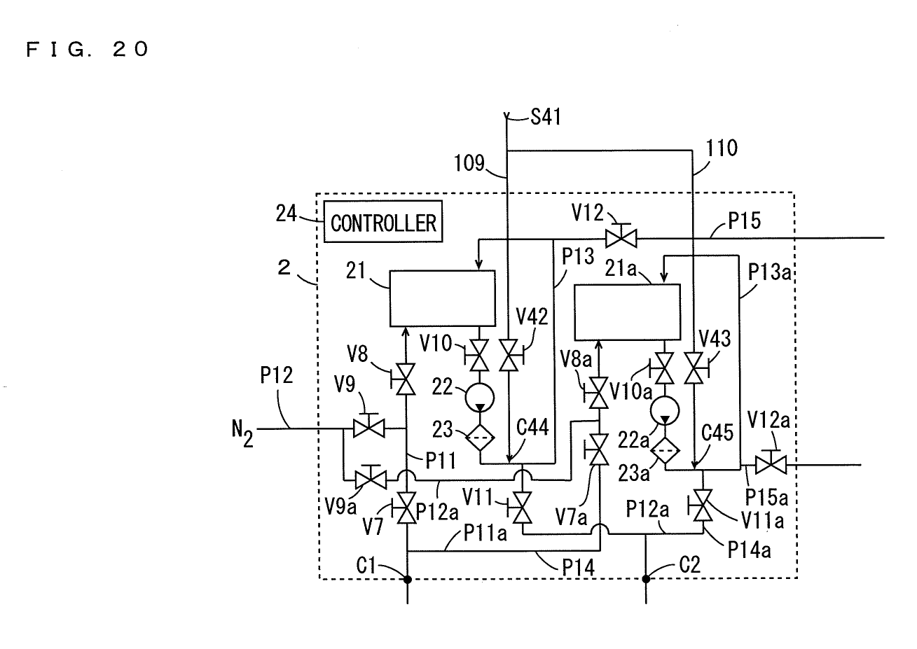

In a substrate processing system according to the fifth embodiment, the configuration of the cleaning unit 1A of FIGS. 14 to 18 are applied to the processing liquid supply unit 2 of the substrate processing system 100 (FIG. 12) according to the second embodiment. FIG. 20 is a schematic diagram showing the configuration of a main part of the processing liquid supply unit in the fifth embodiment.

As shown in FIG. 20, the supplier S41 for a nitrogen gas used as an inert gas is provided in the processing liquid supply unit 2. The supplier S41 is connected to the pipe P13 at the connector C44 through the nitrogen gas supply path 109 having the valve V42. Further, the supplier S41 is connected to the pipe P13a at the connector C45 through the nitrogen gas supply path 110 having the valve V43. In this case, the pipe P13 of FIG. 12 constitutes the circulation path 101 of FIG. 14, the pipe P13a of FIG. 12 constitutes the circulation path 102 of FIG. 14, the pipes P15, P16 of FIG. 12 constitute the discharge paths 103, 104 of FIG. 14, and the pipes P15a, P16a of FIG. 12 constitute the discharge paths 105, 106 of FIG. 14. Further, the valves V12, V13 of FIG. 12 correspond to the valves V61, V66, and the valves V62, V68 of FIG. 14, and the valves V12a, V13a of FIG. 12 correspond to the valves V63, V67, and the valves V64, V69 of FIG. 14.

Such a configuration enables a nitrogen gas to be mixed in the first cleaning liquid circulating through the pipes P13, P13a from the connectors C44, C45 in the steps S3, S4 of FIG. 2. Further, a nitrogen gas can be mixed in the second cleaning liquid circulating through the pipes P13, P13a from the connectors C44, C45 in the steps S6, S7 of FIG. 2. Further, a nitrogen gas can be mixed in the third cleaning liquid circulating through the pipes P13, P13a in the steps S10, S11 of 2 from the connectors C44, C45. Thus, minute particles adhering to the inner walls of the pipes P13, P13a, P15, P15a, P16, P16a, P14, P14a, P9 (FIG. 12) can be removed with high efficiency.

### [7] Other Embodiments

(a) In the above-mentioned first embodiment, the SC1 may be used as the first cleaning liquid, pure water may be used as the second cleaning liquid, the SC2 may be used as the third cleaning liquid, and pure water may be used as the fourth cleaning liquid. In this case, after the steps S1 to S8 of FIG. 2 are performed for the first cleaning liquid and the second cleaning liquid, the steps S1 to S8 are performed for the third cleaning liquid and the fourth cleaning liquid, and then the steps S9 to S13 are performed. Thus, particles in the processing liquid tank 21 and the pipes P13, P15 to P17 can be cleaned with the SC1, and metallic contaminants in the processing liquid tank 21 and the pipes P13, P15 to P17 can be cleaned with the SC2.

(b) In the cleaning unit 1 of FIG. 13, the pipe P2 and the pipe P2a do not have to be connected to each other and may be provided respectively and separately. Further, in the cleaning liquid supply unit 2 of FIG. 12, the pipe P11 and the pipe P11a do not have to be connected to each other, and may be provided respectively and separately. In this case, the pipes P2, P2a of the cleaning unit 1 can be connected to the pipes P11, P11a of the processing liquid supply unit 2, respectively. In this case, the cleaning liquid is supplied from the cleaning liquid tank 11 of FIG. 13 to the processing liquid tank 21 of FIG. 12 through the pipe P2, and the processing liquid is supplied from the cleaning liquid tank 11a of FIG. 13 to the processing liquid tank 21a of FIG. 12 through the pipe P2a.

(c) While the controllers 17, 24, 35 are respectively provided in the cleaning unit 1, the processing liquid supply unit 2 and the substrate processing apparatus 3 in the above-mentioned embodiment, the present invention is not limited to this. A single controller that controls the cleaning unit 1, the processing liquid supply unit 2 and the substrate processing apparatus 3 may be provided instead of the plurality of controllers 17, 24, 35.

### [8] Correspondences Between Constituent Elements in Claims and Parts in Preferred Embodiments

In the following paragraphs, non-limiting examples of correspondences between various elements recited in the claims below and those described above with respect to various preferred embodiments of the present invention are explained.

In the above-mentioned embodiment, the substrate processing apparatus 3 is an example of a substrate processing apparatus, the processing liquid supply units 2, 2a are examples of a processing liquid supply unit, the cleaning unit 1 is an example of a processing unit, the processing liquid tanks 21, 21a are examples of a processing liquid tank, the processing unit 31 is an example of a processing unit, and the pipes P13, P15, P16, P13a, P15a, P16a are examples of a pipe.

Further, the pipes P2, P11, P2a are examples of a supply path, the valves V7, V8, V7a, V8a are examples of an opening closing device, a nitrogen gas is an example of an inert gas or gas, the pipe P12 is an example of an inert gas supplier, and the pipes P13, P13a are examples of a circulation path.

Further, the nitrogen gas supply paths 109, 110 are examples of a gas supplier, the period for the steps S3, S4 is an example of a first period, the period for the steps S6, S7 is an example of a second period, the pipes P15, P16, P15a, P16a are examples of a discharge path, the processing unit 31 is an example of a processing chamber, the nozzle 34 is an example of a nozzle, the valves V12, V13, V12a, V13a are examples of a valve, and the small diameter portion of the T-shape pipe P71 is an example of a pipe path.

As each of constituent elements recited in the claims, various other elements having configurations or functions described in the claims can be also used.

### INDUSTRIAL APPLICABILITY

The present invention can be utilized for cleaning of pipes in a substrate processing system.

1. A substrate processing system comprising:
a substrate processing apparatus that performs processing on a substrate;
a processing liquid supplier that supplies a processing liquid to the substrate processing apparatus through a pipe; and
a cleaner, wherein
the processing liquid supplier includes a processing liquid tank that stores the processing liquid during processing of a substrate,
the substrate processing apparatus includes a substrate processor that supplies the processing liquid to the substrate during processing of the substrate,
the processing liquid tank and the substrate processor are connected to each other by the pipe,
the cleaner is configured to, during cleaning of the pipe, supply a first cleaning liquid to the processing liquid tank of the processing liquid supplier, then prepare a second cleaning liquid, and supply the prepared second cleaning liquid to the processing liquid tank, and
the processing liquid supplier is configured to, during the cleaning of the pipe, store the first cleaning liquid supplied from the cleaner in the processing liquid tank, and then clean the pipe by supplying the first cleaning liquid in the processing liquid tank to the substrate processor through the pipe, and store the second cleaning liquid supplied from the cleaner in the processing liquid tank, and then clean the pipe by supplying the second cleaning liquid in the processing liquid tank to the substrate processor through the pipe, and
the cleaner prepares the second cleaning liquid concurrently with the cleaning of the pipe by the first cleaning liquid.

2. The substrate processing system according to claim 1, further comprising:
a supply path for supplying the first cleaning liquid and the second cleaning liquid from the cleaner to the processing liquid tank; and
an opener-closer that opens and closes the supply path, wherein
the opener-closer opens the supply path during supply of the first cleaning liquid from the cleaner to the processing liquid tank and closes the supply path after the supply of the first cleaning liquid to the processing liquid tank.

3. The substrate processing system according to claim 2, further comprising an inert gas supplier that supplies an inert gas to the supply path and the cleaner after the cleaning of the pipe by the second cleaning liquid.

4. The substrate processing system according to claim 1, wherein
the cleaner is provided to be connectable to and disconnectable from the processing liquid supplier.

5. The substrate processing system according to claim 1, wherein
the processing liquid supplier includes a plurality of the processing liquid tanks, and
the cleaner is configured to be connectable to the plurality of processing liquid tanks.

6. The substrate processing system according to claim 1, wherein
the processing liquid supplier further includes a circulation path that circulates the first cleaning liquid in the processing liquid tank through a filter, and
the cleaner prepares the second cleaning liquid concurrently with circulation of the first cleaning liquid by the circulation path.

7. The substrate processing system according to claim 1, further comprising a gas supplier configured to supply gas to the pipe in at least one period of a first period in which the first cleaning liquid is supplied to the pipe and a second period in which the second cleaning liquid is supplied to the pipe.

8. The substrate processing system according to claim 7, wherein
the gas supplier is configured to continuously supply an amount of the gas that is a supply amount of the first cleaning liquid per unit time or more to the first cleaning liquid supplied to the pipe in the first period.

9. The substrate processing system according to claim 7, wherein
the gas supplier is configured to continuously supply an amount of the gas that is a supply amount of the second cleaning liquid per unit time or more to the second cleaning liquid supplied to the pipe in the second period.

10. The substrate processing system according to claim 7, wherein
the pipe constitutes a circulation path that returns the processing liquid sent from the processing liquid tank to the processing liquid tank, and a discharge path that supplies the processing liquid from the circulation path to the substrate processor, and
the gas supplier is configured to supply the gas to the circulation path in the at least one period.

11. The substrate processing system according to claim 10, wherein
the substrate processing apparatus includes
a processing chamber, and
a nozzle that discharges the processing liquid supplied from the circulation path through the discharge path to the substrate in the processing chamber, wherein
a valve is provided at the discharge path, and
a cleaning liquid that circulates through the circulation path is discharged from the nozzle intermittently by intermittent opening of the valve.

12. The substrate processing system according to claim 11, wherein
the substrate processing apparatus includes
a plurality of the processing chambers, and
a plurality of the nozzles respectively provided in the plurality of the processing chambers,
the pipe constitutes a plurality of the discharge paths,
a plurality of the valves are provided at the plurality of discharge paths, respectively, and
the plurality of valves are opened at time points different from one another in the at least one period.

13. The substrate processing system according to claim 12, wherein
the gas supplier continuously supplies an amount of the gas that is larger than an amount of the first cleaning liquid or the second cleaning liquid supplied per unit time in the at least one period such that gas is discharged from the plurality of nozzles.

14. The substrate processing system according to claim 10, wherein
the gas supplier further includes a pipe path that supplies the gas in a direction same as a direction of a flow of the first cleaning liquid or the second cleaning liquid to the first cleaning liquid or the second cleaning liquid that circulates through the circulation path in the at least one period, and
the pipe path has an inner diameter smaller than an inner diameter of the circulation path.

15. A pipe cleaning method of cleaning a pipe in a substrate processing apparatus and a processing liquid supplier, wherein
the processing liquid supplier is configured to, during processing of a substrate, supply a processing liquid from a processing liquid tank of the processing liquid supplier to a substrate processor of the substrate processing apparatus through the pipe,
the pipe cleaning method includes the steps of
supplying a first cleaning liquid to the processing liquid tank of the processing liquid supplier from a cleaner during cleaning of the pipe,
cleaning the pipe by supplying the first cleaning liquid from the processing liquid tank to the substrate processor of the substrate processing apparatus through the pipe after the supply of the first cleaning liquid to the processing liquid tank,
preparing a second cleaning liquid in the cleaner concurrently with the cleaning of the pipe by the first cleaning liquid,
supplying the second cleaning liquid from the cleaner to the processing liquid tank after the cleaning of the pipe by the first cleaning liquid, and
cleaning the pipe by supplying the second cleaning liquid from the processing liquid tank to the substrate processor through the pipe after the supply of the second cleaning liquid to the processing liquid tank.
